(19) United States
(12) Patent Application Publication
(10) Pub. No.: US 2003/0109142 A1
(43) Pub. Date: Jun. 12, 2003

(54) Integrated photodetector for VCSEL feedback control

(76) Inventors: James S. Cable, San Diego, CA (US); Man W. Wong, San Diego, CA (US); Michael A. Stuber, Carlsbad, CA (US); Charles B. Kuznia, Encintas, CA (US); Joseph F. Ahadian, Carlsbad, CA (US)

Correspondence Address: Stephen C. Durant, Morrison & Foerster LLP, 425 Market St,, San Francisco, CA, 94105-2482, US

(21) Appl. No.: 10/179,687

(22) Filed: Jun. 24, 2002

Related U.S. Application Data
(60) Provisional application No. 60/300,129, filed on Jun. 22, 2001.

(51) Int. Cl. H01L 21/302; H01L 21/461

(52) U.S. Cl. 438/708; 438/689

(57) ABSTRACT

An integrated photodetector means for controlling the output of a light source, where the control means is a photodetector formed on a silicon-on-insulator substrate. The integrated photodetector senses the optical power from the light source and provides an electrical feedback signal which can be used to adjust the DC bias levels of the light source control driver circuit. The approach readily lends itself to large arrays of light sources bonded to silicon-on-sapphire driver circuits and is especially suitable for controlling light sources such as VCSELs in arrays such as are found in communications systems.

### CROSS-REFERENCE TO A RELATED APPLICATION

This application claims priority of U.S. Provisional Patent Application Serial No. 60/300,129, filed Jun. 22, 2001, the disclosure of which is hereby incorporated herein by reference in its entirety.

### BACKGROUND OF THE INVENTION

1. Field of the Invention

The present invention relates to optical communications, in particular to a photodetector for sampling VCSEL light output and providing a signal useful for feedback control of the VCSEL output, and to a method of fabricating the same.

2. Description of Related Art

The vertical cavity surface-emitting laser (VCSEL) has emerged as a new light source alongside the conventional edge-emitting semiconductor laser. Advantages of the VCSEL include its compactness, inherent single-longitudinal mode operation, circular beam profile, low current threshold (as low as 20 μA), low power dissipation, and potential for integration with other electronic circuitry. Vertical-cavity lasers hold promise of superior performance in many optoelectronic applications and lower manufacturing cost than edge-emitting lasers. VCSELs are excellent light sources for optical data links. VCSELs are processed and tested at the wafer level, and one-dimensional or two dimensional arrays suitable for coupling to fiber optic ribbons or matrices are readily fabricated. Light is emitted perpendicular to the substrate with a circular beam that enables efficient, direct fiber or waveguide coupling. Particularly desirable are VCSELs emitting light of wavelength approximately 850 nm. Such VCSELs may be fabricated in high yield and are commercially available (e.g., (Emcore Corp. MODE Division, Albuquerque, N. Mex.).

VCSELs can be directly modulated at very high speeds (>1 GHz) at very low electrical current levels (<5 mA). In optical networks, the light emitted by these VCSELs is then coupled by any number of techniques into an optical fiber or optical waveguide. Optical switching applications envision the VCSEL light signal being transmitted to an optoelectronic device such as a photodetector or modulator. VCSELs operated at 850 nm are relatively cheap to manufacture and as such are being widely used in low cost, high volume optical systems today. To directly modulate a VCSEL, a high-speed electrical driver circuit is required. Such a circuit takes a modulating signal and drives a modulating current into the VCSEL.

The positive attributes of VCSELs are slightly offset by their sensitivity to temperature which changes the optical power output at a given DC bias current level, and to long term aging effects which again cause a change in the optical power output as a function of time. These changes in optical power are problematic at the system level where they have an impact on system signal to noise (S/N) ratio. In order to deal with these effects, VCSELs are packaged with optical photodetectors, which use light reflected from the VCSEL output to sense these optical power changes and adjust the bias voltages/currents of the VCSEL driver circuits.

The mechanical alignment and positioning between the photodetector and VCSEL light source is oftentimes a critical manufacturing step. It is desirable to absorb as little power as possible in the photodiode so that the maximum amount can be coupled into the waveguide which will eventually carry the optical signal downstream in the system.

With the advent of VCSEL arrays, the problem of signal variation becomes more difficult. In a VCSEL array configuration, there is an array of electrical driver circuits—one driver for each VCSEL. There are inevitably some manufacturing differences in the electrical/optical conversion properties of the individual elements of the array. Hence there are variations in optical power from each. For a parallel system based on an array of VCSELs, there are a variety of issues associated with how the previously mentioned effects of temperature and aging can be dealt with. While a single photodetector could sense temperature changes and apply a feedback signal to the entire array of driver circuits, the aging processes across the different elements are not identical. In addition, the manufacturing tolerances of the VCSELs result in some amount of optical power variations across the various elements of the array. In such a parallel system, it is important to have the power from each element be the same.

Because of these problems, there is an important challenge to find a means of modulating the signals from an array of VCSELs to compensate for non-uniformities that result from environmental effects, differential aging, and manufacturing variations. To be useful, such a method will not consume an excessive amount of power and will not add undue complexity to the manufacturing of the system.

Hence there is a need for a suitable photodetector and an associated feedback control means to the VCSEL. A suitable photodetector will be capable of sampling a very small portion of the VCSEL light emission, detecting the changes or variations in light emission described earlier, and providing a signal that can be used for feedback control to the VCSEL driver circuit. The photodetector will preferably be integrated on the same substrate as the VCSEL driver circuit, to avoid adding delay and parasitics. Since VCSEL driver circuits are most typically CMOS circuits fabricated in silicon, this means that the photodetector should also be based in silicon.

In optical networks or switching systems operating at very high speeds (>1 GHz), the limitations of silicon substrates become important, and silicon-on-insulator (“SOI”) devices can have significant performance advantages. However, in the past, it has been difficult to fabricate photosensors in the needed visible-to-IR wavelength range on SOI substrates, because of the limited depth of silicon available in the top film, resulting in limited photon absorption capability. Yet SOI is very appealing as a basis for advanced optical networking and switching devices; its advantages include the substantial reduction of parasitic capacitance between charged active regions and the substrate and the effective elimination of leakage currents flowing between adjacent active devices.

Therefore, a photodetector suitable for VCSEL feedback control will preferably be capable of being fabricated in silicon, on SOI substrates, and thus the problem of insufficient light being absorbed to provide an adequate signal must be addressed.

Furthermore, a photodetector suitable for VCSEL feedback control should be capable of being fabricated on the same substrate as the VCSEL driver circuit without adding undue complexity to the device processing scheme. Its requirements, e.g., for light access to the body of the transistor, should not require changes in processing to the use of less desirable materials or steps. It would be advantageous to be able to fabricate the CMOS circuitry including the photodetector using silicided gates. Silicided gates provide the advantages of lower resistance along the gate and hence faster operation, important for high speed circuits; silicide straps together p-type and n-type gates allowing a more compact layout, again enabling higher speed and density. However, the metal silicides used for silicided gates block the transmission of most incident light. With the use of self-aligned silicide (“salicide”) processes, which are desirable because the silicide layers on the source and drain regions provide lower resistance and increased speed, no light will reach the channel region through the source or drain either.

In several recent reports, Zhang et al. have described a photodetector fabricated on an SOI substrate using a standard CMOS process. (“High responsivity photo-sensor using gate-body tied SOI MOSFET,” 1998 IEEE International SOI Conference Proceedings, Stuart, Fla., USA, Oct. 5-8, 1998, IEEE, New York, 1998. p.149-50; “High gain gate/body tied NMOSFET photo-detector on SOI substrate for low power applications,” Solid-State Electronics (March 2000) vol.44, no.3, p.535-40; “Performance of the Floating Gate/Body Tied NMOSFET Photodetector on SOI Substrate,” IEEE Transactions on Electron Devices (July 2000), Vol. 47, no. 7, p. 1375-1384). This photosensor is formed by connecting the gate and body of an NMOSFET fabricated with a DTMOS (dynamic threshold MOSFET) process.

DTMOS operation is suitable for ultra-low voltage VLSI circuits (Assaderaghi et al. IEDM94, pp. 809-12, 1994; also IEEE Transactions on Electron Devices (March 1997), vol. 44, no. 3, p. 414-422). The threshold voltage of a DTMOS transistor is a function of its gate voltage. As the gate voltage increases, the threshold voltage drops, resulting in a much higher current drive than standard MOSFET devices. On the other hand, the threshold voltage is high when the gate voltage is low, leading to low leakage current.

In the photosensor of Zhang, the gate-body terminal is left floating so that the potential can be modulated by illumination. The depletion region induced by the floating gate separates the optically generated electron-hole pairs in the direction perpendicular to the current. This increases the body potential and induces positive charges to the gate due to the gate/body tie. It results in further turn-on of the DTMOS transistor and extra light-induced drain current. A wide signal range of more than six orders of magnitude and a maximum responsivity of 1.2×10³ A/W were obtained with an operating voltage as low as 0.2 V over a wide range of illumination intensities. With dimensions of 5 μm width by 2 μm length, the optical current generated was of the order of microamperes, which was directly read out for processing. Zhang et al. proposed that speed and responsivity could be further increased by reducing the channel length.

This type of photodetector is useful in the wavelength region that is of interest for optical networks, in the infrared to visible range, especially in the wavelengths around approximately 850 nm. However, the Zhang photosensor is a pure photodiode, and while its drain current varies in response to light over a wide range of illumination intensities (over several orders of magnitude, e.g. 0.1 to 100 mW/cm²), it is not designed or suitable for detecting the smaller variations in light intensity that can occur between VCSELs in an array. Furthermore, a photodetector suitable for providing a signal to be used for feedback control of an individual VCSEL's light emission must sample only a small portion of the VCSEL light, since the purpose of the VCSEL signal is to be used for data transmission or switching. The requirement for light access to the body of the DTMOS detector of Zhang means that the gate must be polysilicon so that light will be transmitted through to the channel region.

PIN diodes represent an alternate type of light detector that may be fabricated in silicon for sensing light in the wavelength ranges of interest. However, typical PIN diodes are fabricated vertically, and to attain useful sensitivity, a relatively thick silicon layer is required. In high performance SOI circuits, the silicon layer is typically thin, e.g. less than a few hundred nanometers, and thus vertical PIN diodes are not feasible.

### SUMMARY OF THE INVENTION

The present invention addresses the limitations of previous approaches by providing photodetectors that yield signals suitable for VCSEL feedback control via the VCSEL driver circuits. The photodetectors of the invention are integrated on the same substrate as the VCSEL driver circuits and can be fabricated by the same CMOS processing steps that are used to make the driver circuits, with no need for compromises in choice of optimal processing technology. The photodetectors are readily fabricated in arrays for use in sensing and modulating the output of VCSELs in arrays. The photodetectors are fabricated on SOI substrates and are suitable for use in high speed optical datacom or switching networks.

In one aspect, the invention provides a light sensing device comprising a sapphire substrate having a silicon layer disposed on a top surface thereof, including one or more optically transparent areas in the silicon layer, through which light of a prescribed wavelength may pass despite the silicon layer; and a photodetector formed in the silicon layer adjacent to a transparent area. The top surface of the sapphire substrate is provided with one or more alignment features, and the photodetector is formed in the silicon layer in a prescribed spatial relationship with at least one alignment feature. Other features are also formed on the top surface of the sapphire substrate in a prescribed spatial relationship with the alignment features to enable the efficient assembly of an integrated system that aligns the photodetector to a light source device, e.g., a vertical cavity surface emitting laser, an edge-emitting laser, or a light emitting diode. For example, an optically transparent area and bonding pads may be formed on the top surface of the sapphire substrate in prescribed spatial relationships with the alignment features. A VCSEL chip bearing corresponding bonding pads on its top surface (the surface from which light is emitted, primarily normal to the surface) may be attached to the respective bonding pads on the top surface of the sapphire substrate by the technique of flip chip bonding. The location of the bonding pads on the top surface of the sapphire substrate defines the position of the flip-chip bonded VCSEL, which is preferably situated to emit light through a transparent area in the silicon layer and to enable a portion of the emitted light to impinge on and be sensed by the photodetector.

The invention further comprises a sapphire substrate having a silicon layer disposed on a top surface thereof, including multiple respective optically transparent areas through which light of a prescribed wavelength may pass despite the silicon layer; and multiple respective photodetectors formed in the silicon layer adjacent different respective transparent areas of the sapphire substrate. The top surface of the sapphire substrate is provided with one or more alignment features, and the multiple photodetectors are formed in the silicon layer in a prescribed spatial relationship with at least one alignment feature.

In another aspect, the invention provides an integrated photodetector means for controlling the output of a VCSEL, where the control means is a photodetector formed in the silicon layer of a silicon-on-sapphire substrate. The integrated photodetector senses the optical power from the VCSEL source and provides an electrical feedback signal which is used to adjust the DC bias levels of the VCSEL driver circuit. The integrated photodetector means comprises a sapphire substrate; a silicon layer disposed on the sapphire substrate so as to define a transparent area of the sapphire substrate through which light of a prescribed wavelength may pass despite the silicon layer; a photodetector formed in the silicon layer adjacent the clear portion of the sapphire substrate; a light source disposed to emit light into the clear portion of the sapphire substrate adjacent to the photo-detector; and a light source control circuit electrically coupled to an output of the photodetector and to a control input of the light source.

The invention further comprises at least one alignment feature formed in the silicon layer; wherein respective photodetectors are formed in the silicon layer in a prescribed spatial relationship with the at least one alignment feature; and wherein respective light sources are disposed in prescribed spatial relationships with the at least one alignment feature; wherein the sapphire substrate and the respective light sources are disposed relative to one another such that a front surface of the sapphire substrate with the silicon layer formed thereon faces toward the respective light sources; and wherein respective photo-detectors and respective light sources are aligned with respect to the at least one alignment feature such that a sufficient amount of respective light emitted by respective light sources into respective clear portions reflects onto respective photodetectors, from a back surface of the sapphire substrate opposite a sapphire substrate front surface on which the silicon layer with the respective photodetectors are formed, to cause respective photodetectors to produce respective output signals indicative of respective emitted light power levels.

In another aspect, the invention provides an integrated VCSEL/photodetector system comprising a VCSEL flip-chip bonded to a silicon-on-sapphire wafer bearing a VCSEL driver circuit and a photodetector formed in the silicon layer and configured to sample light emitted by the VCSEL and provide a signal for feedback control of the VCSEL. The integrated VCSEL/photodetector uses a flip-chip approach and is based on the transparency of the sapphire at the wavelengths of interest, in the visible and infrared range, especially in the range of approximately 850 nm. No other widely used semiconductor material has adequate transparency at this wavelength to allow for such an assembly concept. The concept of a flip-chip bonded VCSEL laser attached to a silicon-on-sapphire substrate which contains active electronics in the silicon layer was described in U.S. patent application Ser. No. 09/658,259, filed Sep. 8, 2000, the disclosure of which is hereby incorporated herein by reference.

In one embodiment, the invention provides a photodetector circuit fabricated on a silicon-on-insulator substrate, comprising a photovoltaic mode DTMOS photodetector and a post amplifier. The photodetector circuit comprises two transistors, (1) a MOS dynamic threshold (DTMOS) transistor whose body is electrically tied to its gate, which is electrically floating and has electrical connection only to (2) the input of an amplifier characterized by high input impedance, which may be the gate of a second MOS transistor. The amplifier processes the signal generated by charges induced by light absorbed in the body of the transistor. Light absorbed in the body of the DTMOS transistor generates an electrical potential in the body of the DTMOS transistor. The body of the DTMOS transistor is electrically connected to its gate, and hence its gate potential is also increased. Since this floating gate is connected to the gate of the second MOS transistor, the gate potential of the second MOS transistor is consequently increased. By biasing the body of the DTMOS transistor very close to the threshold voltage of the second MOS transistor of the post amplifier, small changes in light illumination intensity can cause large changes in the. The output current to input light power relationship can be tuned using the geometric parameters of the device width and length of both transistors, the ratios of these widths and lengths, and the threshold voltages of the two transistors. In addition, the biasing applied to the both devices can be used to tune the ratio of incident light intensity to output current. By optimizing these parameters, a large current signal, on the order of milliamperes, can be obtained from the second transistor, in contrast to the earlier DTMOS photosensor, which provided a current signal of a few microamperes.

In a preferred embodiment, the DTMOS photodetector circuit, fabricated on a silicon-on-insulator substrate, comprises two transistors, (1) a MOS dynamic threshold (DTMOS) transistor whose body is electrically tied to its gate, which is electrically floating and has electrical connection only to the gate of (2) a second MOS transistor. Light absorbed in the body of the DTMOS transistor generates an electrical potential in the body of the DTMOS transistor. The body of the DTMOS transistor is electrically connected to its gate, and hence its gate potential is also increased. Since this floating gate is connected to the gate of the second transistor, the gate potential of the second transistor is consequently increased. By biasing the body of the DTMOS transistor very close to the threshold voltage of the second transistor, small changes in light illumination intensity can cause large changes in the current through the second transistor. The output current to input light power relationship can be tuned using the geometric parameters of the device width and length of both transistors, the ratios of these widths and lengths, and the threshold voltages of the two transistors. In addition, the biasing applied to the both devices can be used to tune the ratio of incident light intensity to output current. By optimizing these parameters, a large current signal, on the order of milliamperes, can be obtained from the second transistor, in contrast to the earlier DTMOS photosensor, which provided a current signal of a few microamperes.

In a further aspect of the invention, the photodetector includes a third biasing transistor. The bias voltage of this third transistor is used to set the operating points of the first and second transistors. The bias voltage of the third transistor may be increased sufficiently to indirectly tune the gate voltages of the first and second transistors close to their threshold voltages Vₜ. Changes in light illumination intensity cause changes in the gate potentials of the first and second transistor leading to relatively large increases in output current.

The current through the second output transistor of the photodetector may be converted to a voltage and applied to the gate of the DC bias transistor of a VCSEL driver circuit.

An embodiment of the invention provides a DTMOS photodetector formed in silicon-on-sapphire, comprising two NMOS transistors, wherein: the first NMOS transistor is a DTMOS transistor whose body is electrically tied to its gate, which is electrically floating and has electrical connection only to the gate of the second NMOS transistor; and the second NMOS transistor is turned on by charges induced by light absorbed in the body of the DTMOS transistor.

An embodiment of the invention provides a photodetector formed on a silicon-on-insulator substrate, configured for controlling the output of a VCSEL, wherein:

(1) the VCSEL is bonded to the silicon-on-sapphire substrate and positioned so that its light emission impinges on the photodetector; and

(2) the photodetector comprises two NMOS transistors, wherein: the first NMOS transistor is a DTMOS transistor whose body is electrically tied to its gate, which is electrically floating and has electrical connection only to the gate of the second NMOS transistor; and the second NMOS transistor is turned on by charges induced by light absorbed in the body of the DTMOS transistor; and

(3) the current output from the second NMOS transistor is used to provide feedback control to the VCSEL.

Feedback control to the VCSEL may be provided by, for example, converting the current output from the drain of the second NMOS transistor to a voltage for biasing the gate of the DC bias transistor of a VCSEL driver circuit.

In another aspect, the invention provides an array of VCSELs bonded to a silicon-on-sapphire substrate and having their output controlled by one or more DTMOS photodetectors on the silicon-on-sapphire substrate. Each VCSEL may be controlled by one DTMOS photodetector, or the DTMOS photodetectors may be configured to control more than one VCSEL. Such an integrated VCSEL/photodetector system comprises (1) a VCSEL; and (2) a VCSEL driver circuit and a photodetector both formed on a silicon-on-insulator substrate, wherein: the VCSEL is bonded to the silicon-on-insulator substrate, in electrical communication with the VCSEL driver circuit, and positioned so that its light emission impinges on the photodetector, The photodetector comprises two NMOS transistors, wherein the first NMOS transistor is a DTMOS transistor whose body is electrically tied to its gate, which has electrical connection only to the gate of a second NMOS transistor; the gate potential of the second NMOS transistor increases in response to increases in the gate potential of the DTMOS transistor induced by absorption of light in the body of the DTMOS transistor; and the current output from the second NMOS transistor is transmitted to the VCSEL driver circuit. This integrated VCSEL/photodetector system may also include a current mirror circuit for converting the current output from the second NMOS transistor to a voltage signal for transmission to the VCSEL driver circuit. The voltage signal is used to bias the gate of a DC bias transistor of the VCSEL driver circuit.

In another aspect, the invention provides an optical network VCSEL assembly, comprising at least one VCSEL; its required VCSEL driver circuitry; and VCSEL modulating means including a photodetector. In this network, the photodetector is typically arranged so that it receives only a minor fraction of light emitted from said VCSEL. The VCSELs may be present in the form of an array. The VCSEL driver circuitry and the VCSEL modulating means are integrated in the silicon layer on a same substrate, which is an SOI substrate, preferably silicon on sapphire, and more preferably, a UTSi substrate. The VCSEL driver circuitry and the VCSEL modulating means are integrated on a first substrate, and said first substrate is flip-chip bonded to a second substrate comprising said at least one VCSEL therein. In some embodiments, the photodetector comprises a DTMOS transistor and an NMOS transistor, wherein the DTMOS transistor has an electrically floating gate that is (i) electrically coupled to its body, and (ii) connected to a gate of the NMOS transistor, arranged so that the NMOS transistor generates a signal for modulation of the VCSEL driver circuitry in response to light absorbed by the body of the DTMOS from light emitted from said VCSEL.

In an aspect of the invention, an optical network VCSEL assembly can comprise a multiplicity of VCSELs and a multiplicity of VCSEL modulating means, typically arranged in an array format. The array's functioning is enhanced by the integrated photodetectors, which, together with signal processing and driver circuitry, comprise a feedback control unit for VCSELs having driver circuitry coupled therewith and operatively arranged to selectively modulate the VCSEL's light emission. The VCSELs may be components of an optical communications network or an optical switching device. The photodetectors may be laid out so that they receive a relatively small portion, e.g., less than about 10%, of light emitted from the VCSELs.

The invention provides a photodetector for monitoring light emission from a VCSEL and producing a correlative output. In one embodiment, said detector comprises a DTMOS transistor including electrically coupled gate and body, with the gate being electrically floating and electrically connected to a gate of a NMOS transistor, so that light from the VCSEL impinging on the body of the DTMOS transistor produces an electrical output signal from said NMOS transistor. In another embodiment, said detector comprises a lateral PIN diode

In yet another aspect, the invention provides a method of modulating an optical signal from a VCSEL to compensate for an optical signal-altering condition. The method comprises monitoring an optical signal with a photodetector and responsively adjusting power input to the VCSEL using the electrical output signal to compensatorily modulate the optical signal.

### BRIEF DESCRIPTION OF THE DRAWINGS

FIG. 1 shows an electrical schematic representation of one embodiment of the photodetector of the present invention, comprising a DTMOS transistor.

FIG. 2 shows an electrical schematic representation of a second embodiment of the photodetector of the present invention, comprising a DTMOS transistor.

FIG. 3 shows an electrical schematic representation of one embodiment of the photodetector of the present invention configured to provide an output voltage signal that is usable to control the operation of a VCSEL.

FIGS. 4A and 4B show performance data in the form of plots of output voltage gain vs. input optical power for a DTMOS photodetector of the invention.

FIG. 5A shows schematically one example of a method of positioning of the photodetector with respect to a VCSEL flip chip bonded to a silicon on sapphire substrate.

FIGS. 5B and 5C show top view schematics of two layouts of the DTMOS transistor used in this photodetector embodiment. FIGS. 5D and 5E show cross-sections of the layout shown in FIG. 5C.

FIG. 6A shows schematically a second example of a method of positioning of the photodetector with respect to a VCSEL flip chip bonded to a silicon on sapphire substrate.

FIG. 6B shows an electrical schematic of this configuration. FIG. 6C shows a top view schematic of one example of DTMOS transistor layout. FIG. 6D shows a top view schematic of a DTMOS transistor layout comprising an annular transistor.

FIG. 7A shows schematically a third example of a method of positioning of the photodetector with respect to a VCSEL flip chip bonded to a silicon on sapphire substrate.

FIG. 7B shows a schematic cross section of this configuration.

FIG. 8 shows a block diagram of the operation of the VCSEL with feedback control provided by the integrated photodetector of the invention.

FIG. 9 shows schematically a PIN photodetector configured to operate in the photodiode mode.

FIG. 10 shows schematically a PIN photodetector configured to operate in the photovoltaic mode.

FIG. 11 shows schematically a cross section of a layout for forming the detector of FIG. 9.

FIG. 12 shows schematically a top view of a layout for forming the detector of FIG. 10.

FIG. 13 shows schematically a layout for a PIN photodetector that surrounds a transparent area suited for light transmission from a light source device.

FIG. 14 shows schematically the SDBLOCK layer of the PIN photodetector layout of FIG. 13.

FIG. 15 shows schematically a layout for a PIN photodetector configured to operate in a transmission geometry.

FIG. 16 shows schematically the SDBLOCK layer of the PIN photodetector layout of FIG. 15.

FIG. 17 shows schematically a PIN photodetector provided with a reflective coating to enhance light capture.

### DETAILED DESCRIPTION OF THE INVENTION, AND PREFERRED EMBODIMENTS THEREOF

Previously, silicon-on-insulator (SOI) has been used for high performance microelectronics, primarily for applications requiring radiation hardness or high speed operation. Fabrication of devices on an insulating substrate requires that an effective method for forming silicon CMOS devices on the insulating substrate be used. The advantages of using a composite substrate comprising a monocrystalline semiconductor layer, such as silicon, epitaxially deposited on a supporting insulating substrate, such as sapphire, have been well-recognized, and can be realized by employing as the substrate an insulating material, such as sapphire (Al₂O₃), spinel, or other known highly insulating materials, and providing that the conduction path of any interdevice leakage current must pass through the substrate.

An “ideal” silicon-on-insulator wafer may be defined to include a completely monocrystalline, defect-free silicon layer of sufficient thickness to accommodate the fabrication of active devices therein. The silicon layer would be adjacent to an insulating substrate and would have a minimum of crystal lattice discontinuities at the silicon-insulator interface. Early attempts to fabricate this “ideal” silicon-on-insulator wafer were frustrated by a number of significant problems, which can be summarized as (1) substantial incursion of contaminants into the epitaxially deposited silicon layer, especially the p-dopant aluminum, as a consequence of the high temperatures used in the initial epitaxial silicon deposition and the subsequent annealing of the silicon layer to reduce defects therein; and (2) poor crystalline quality of the epitaxial silicon layers when the problematic high temperatures were avoided or worked around through various implanting, annealing, and/or regrowth schemes.

It has been found that these high quality silicon films suitable for demanding device applications can be fabricated on sapphire substrates by a method that involves epitaxial deposition of a silicon layer on a sapphire substrate, low temperature ion implant to form a buried amorphous region in the silicon layer, and annealing the composite at temperatures below about 950° C. Examples of and methods for making such silicon-on-sapphire devices are described in U.S. Pat. Nos. 5,416,043 (“Minimum charge FET fabricated on an ultrathin silicon on sapphire wafer”); 5,492,857 (“High-frequency wireless communication system on a single ultrathin silicon on sapphire chip”); 5,572,040 (“High-frequency wireless communication system on a single ultrathin silicon on sapphire chip”); 5,596,205 (“High-frequency wireless communication system on a single ultrathin silicon on sapphire chip”); 5,600,169 (“Minimum charge FET fabricated on an ultrathin silicon on sapphire wafer”); 5,663,570 (“High-frequency wireless communication system on a single ultrathin silicon on sapphire chip”); 5,861,336 (“High-frequency wireless communication system on a single ultrathin silicon on sapphire chip”); 5,863,823 (“Self-aligned edge control in silicon on insulator”); 5,883,396 (“High-frequency wireless communication system on a single ultrathin silicon on sapphire chip”); 5,895,957 (“Minimum charge FET fabricated on an ultrathin silicon on sapphire wafer”); 5,920,233 (“Phase locked loop including a sampling circuit for reducing spurious side bands”); 5,930,638 (“Method of making a low parasitic resistor on ultrathin silicon on insulator”); 5,973,363 (“CMOS circuitry with shortened P-channel length on ultrathin silicon on insulator”); 5,973,382 (“Capacitor on ultrathin semiconductor on insulator”); and 6,057,555 (“High-frequency wireless communication system on a single ultrathin silicon on sapphire chip”).

By the methods described in the patents listed above, electronic devices can be formed in an extremely thin layer of silicon on an insulating synthetic sapphire wafer. The thickness of the silicon layer is typically less than 150 nm. Such an “ultrathin” silicon layer maximizes the advantages of the insulating sapphire substrate and allows the integration of multiple functions on a single chip. Traditional transistor isolation wells required for thick silicon are unnecessary, simplifying transistor processing and increasing circuit density. To distinguish these above-referenced methods and devices from earlier thick-silicon embodiments, they are herein referred to collectively as “ultrathin silicon-on-sapphire.”

In preferred embodiments of the invention, the MOS transistors are formed in ultrathin silicon-on-sapphire wafers by methods disclosed in U.S. Pat. Nos. 5,416,043; 5,492,857; 5,572,040; 5,596,205; 5,600,169; 5,663,570; 5,861,336; 5,863,823; 5,883,396; 5,895,957; 5,920,233; 5,930,638; 5,973,363; 5,973,382; and 6,057,555. As described and claimed in these patents, any processing of the silicon layer which subjects it to temperatures in excess of approximately 950° C. is performed in an oxidizing ambient environment. The thin silicon films in which the transistors are formed typically have an a real density of electrically active states in regions not intentionally doped which is less than approximately 5.×10¹¹ cm².

In the practice of the invention, the light source devices, e.g., VCSEL(s), are integrated with CMOS circuitry formed in silicon layers formed on a transparent substrate. The CMOS circuitry includes controlling circuitry for the light source device, e.g., the VCSEL driver circuit(s). Integrated electronic/optoelectronic modules, comprising discrete optoelectronic devices and CMOS circuitry in silicon-on-sapphire, integrated by the flip-chip bonding methods disclosed in U.S. patent application Ser. No. 09/658,259, “Integrated Electronic-Optoelectronic Devices,” filed Sep. 8, 2000, previously cited and incorporated by reference, are herein referred to as “flip-chip optoelectronic/silicon-on-sapphire modules” or “flip-chip optoelectronic/silicon-on-insulator modules.” Preferred embodiments of the invention employ VCSEL(s) flip-chip bonded to silicon-on-sapphire substrates.

The integrated VCSEL/photodetector system can be implemented using transparent insulating substrates. In the context of the optical/optoelectronic coupling structures, “transparent substrates” are substrate materials that, at the wavelength of interest, transmit sufficient light for signal transmission purposes. Sapphire is a preferred substrate material, with CMOS circuitry formed in silicon layers formed in selected regions on a top surface thereof.

The flip-chipped light source device, e.g., VCSEL, is preferably situated to emit light through a transparent area in the silicon layer and to enable a portion of the emitted light to impinge on the photodetector. As used herein, “transparent areas” refers to regions of the silicon-on-sapphire structure that, at the wavelength of interest, transmit sufficient light for signal transmission purposes. Sapphire is transparent at wavelengths of about 300 nm through about 10 μm. At the wavelengths used in many current fiber optic systems, e.g. in the range of about 850 nm, silicon is considered opaque. Sapphire is transparent at this wavelength, as are some other oxide materials, e.g., SiO₂. Transparent areas may be provided in the silicon layer on the top surface of the sapphire substrate by etching. Alternatively, any non-device areas may be oxidized to Sio₂, which is optically clear.

The arrangement of the VCSEL to emit light primarily through a transparent area in the silicon layer is important to its performance, as it avoids back-reflection of light into the active area of the VCSEL and consequent output instability. To accomplish this while still sampling a usable portion of light, the invention provides novel detector conformations wherein the structures (transistors etc.) that form the detector may be laid out around the outer edge of the area of the light beam impingement on the sapphire substrate. For example, a VCSEL having a divergence angle of theta traveling through sapphire of thickness d will have a beam radius of roughly 2*d*tan(theta) at the photodetector. Therefore, the photodetector should preferably be formed within this region, centered around the transparent area. Such a layout will provide improved performance over detectors set up for monitoring the entire beam, either by passing the beam directly through the photodetector or by reflecting the entire beam off a lens/grating into a photodetector more remotely situated. The preferred layout of the invention does not capture the entire reflected beam and does not require any lens or grating to direct light to a remote photodetector. At wavelengths used in optical communication, e.g. about 850 nm, it should be noted that silicon is very reflective (greater than 18%). Forming a photodetector in silicon directly in the light path of the VCSEL would cause serious degradation to the VCSEL output due to back-reflected light into the VCSEL. Further, the preferred layout of the invention avoids the use of lenses which cause back-reflected light to be focused back into the VCSEL, which also causes VCSEL performance degradation.

Preferred photodetectors will have sufficient sensitivity at optical communications wavelengths to provide a usable signal based on sampling the light emitted by the light source device and are capable of being fabricated in thin layers of silicon on insulating substrates. Especially preferred photodetectors have sufficient sensitivity at optical communications wavelengths to provide a usable signal based on sampling the light emitted by VCSELs and are capable of being fabricated in ultra-thin silicon on sapphire. Further, the preferred photodetectors will be capable of being fabricated in toroidal, square, or any other geometric forms for surrounding a VCSEL-light-transmitting transparent area of the substrate. Examples of preferred photodetectors include DTMOS detectors and lateral PIN diodes.

In one aspect, the present invention provides a novel SOI photodetector that is based on the concept of the Dynamic Threshold MOS (DTMOS) transistor described above. The Zhang et al. photodetector operated as a current mode photodiode, converting light into current. By contrast, in the DTMOS photodetector of the present invention, light absorbed in the body of the DTMOS transistor generates charge and turns on the photodetector transistor, and one or more than one stage or amplification to the photodetector signal is added to form a complete structure. The result is a strong transistor, of aspect ratio on the order of 10000×0.5, capable of output of hundreds of milliamperes.

The physical structure of the “DTMOS photodetector” of the invention consists of two transistors. The first transistor is a DTMOS transistor, whose salient feature is that its body is electrically tied to its gate. The gate of this DTMOS transistor is electrically floating. Its only connection is to the high impedance input of a post amplifier. Typical input impedance of the post amplifier is in the range of hundreds of mega-ohms to several giga-ohms. For example, a typical gate terminal of a MOS device has an input impedance of giga-ohms. The voltage output signal of the post amplifier can thus be a measure of the optical power absorbed in the DTMOS transistor. The external connection of the source terminal of the DTMOS device is used for adjusting the operating point of the post amplifier. The value of the external bias connection depends on the post amplifier design. In the case of the simple NMOS input device with an active current source, the bias level should be slightly below or at the threshold voltage of the post amplifier input device. For example, it may be within 50 mV of the threshold of the post amplifier input device. The post amplifier may comprise a second NMOS transistor, and its input is the gate of the second transistor. The current of this second transistor can thus be a measure of the optical power absorbed in the body of the DTMOS transistor. These transistors and a current source can be configured in a variety of ways.

In another aspect, the present invention employs a photodetector comprising a lateral PIN diodes with a current integrator as the amplifier stage. The PIN photodetector operates as a current mode photodiode and its output signal is a current in the range of a few hundreds nanoamperes over the optical power range of a few milliwatts. The output current can be integrated over a time interval of a few microseconds on an integrated capacitor of size in the range of hundreds of femtofarads will produce a voltage signal level in the hundreds of millivolts range.

The invention is described in detail with reference to the figures. Similar numerals refer to similar structures within successive figures. The figures are generally illustrative and are not shown to scale or in exact proportion.

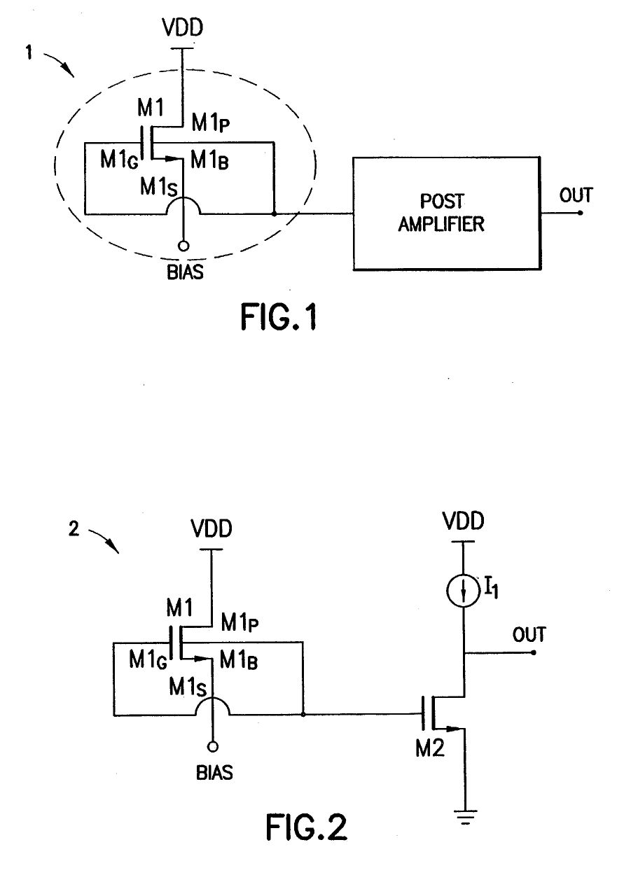

FIG. 1 shows an electrical schematic representation of one example of a DTMOS photodetector circuit 1 of the present invention, comprising a DTMOS transistor M1, whose gate M1_{G} and body M1_{B} are connected to a post amplifier. M1_{S} of DTMOS transistor M1 is connected to a bias voltage to preset the operating points of the DTMOS transistor M1 and the input gate of the post amplifier. Normally the bias voltage is set sufficiently high that the gate voltage of transistor M1 and the input gate of the post amplifier is at a value close to their threshold voltage Vₜ. Light absorbed in the body M1_{B} generates an electrical potential in M1_{B}, which is electrically connected to the gate M1_{G}, thus increasing the gate potential. Since this floating gate M1_{G} is connected to the input gate of the post amplifier, and that gate potential is increased beyond its threshold voltage, resulting in an increase of its output current. The post amplifier therefore serves as a gain or amplification stage to the DTMOS transistor M1. The amount of gain or amplification can be determined by the ratio of gate width to length (W/L) for the input gate of the post amplifier to (W/L) for M1.

FIG. 2 shows an electrical schematic representation of one example of a DTMOS photodetector circuit 2 of the present invention, comprising a DTMOS transistor M1, whose gate M1_{G} and body M1_{B} are connected to the gate M2_{G} of a second NMOS transistor M2, whose drain M2_{D} is connected to current source I₁. M1_{S} of DTMOS transistor M1 is connected to a bias voltage to preset the operating points of the DTMOS transistor M1 and the second NMOS transistor M2. Normally the bias voltage is set sufficiently high that the gate voltage of transistors M1 and M2 is at a value close to their threshold voltage Vₜ. Light absorbed in the body M1_{B} generates an electrical potential in M1_{B}, which is electrically connected to the gate M1_{G}, thus increasing the gate potential. Since this floating gate M1_{G} is connected to the gate M2_{G} of the second NMOS transistor, the gate potential of M2_{G} is increased beyond its threshold voltage, resulting in an increase of its output current. M2 therefore serves as a gain or amplification stage to the DTMOS transistor M1. The amount of gain or amplification can be determined by the ratio of gate width to length (W/L) for M2 to (W/L) for M1.

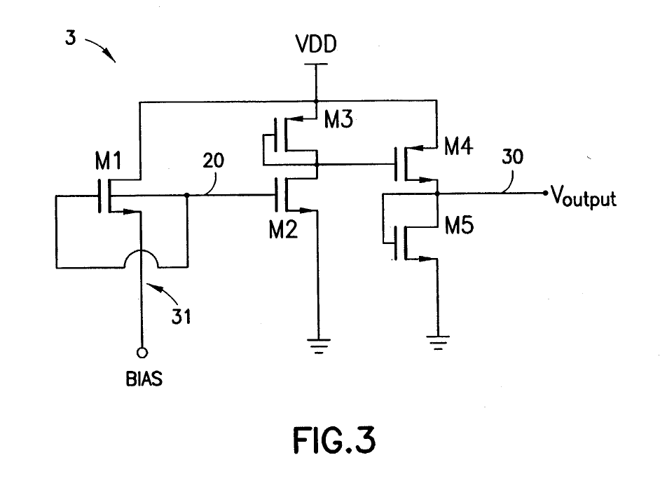

In an integrated system comprising a VCSEL, a VCSEL driver, and a photodetector, the signal derived from the change in current through the output transistor of the photodetector may be converted to a voltage signal. A feedback circuit is constructed which uses this voltage signal to control the DC biasing of the VCSEL driver circuits. A variety of approaches are possible for performing this electrical feedback function. One example is shown schematically in FIG. 3.

FIG. 3 shows an electrical schematic representation of one embodiment of the photodetector of the present invention configured to provide an output signal in the form of a voltage signal that is usable to control the operation of a VCSEL. A diode-connected PMOS current source transistor M3 has its gate connected to the gate of PMOS transistor M4, whose source is connected to the drain and gate of NMOS transistor M5, to provide a current mirror for converting the drain current of M1 to a voltage signal at 30, Vₒᵤₜₚᵤₜ. M1 and M2 are as shown in FIG. 1.

In this illustration, by setting the source voltage of the DTMOS transistor to control the turn-on voltage (Vgs) to a very small value, a small change in optical light power can cause large changes in the gate voltage of the DTMOS transistor. The output voltage to input light power relationship, that is, the sensitivity of the photodetector, can be tuned using the geometric parameters of the device width and length of the gate of the M1 transistor which is exposed to light.

For example, a detector suitable for monitoring the light intensity fluctuations of a commercial VCSEL operating at a wavelength of approximately 850 nm was built using the UTSi FA single metal 0.5μ CMOS process, designed as shown in FIG. 3. The NMOS transistors had the following sizes:

| M | W (μ) | L (μ) |
|---|---|---|
| M1 | 160 | 60 |
| M2 | 100 | 1 |
| M3 | 2.4 | 0.5 |
| M4 | 4 | 1 |
| M5 | 2 | 0.8 |

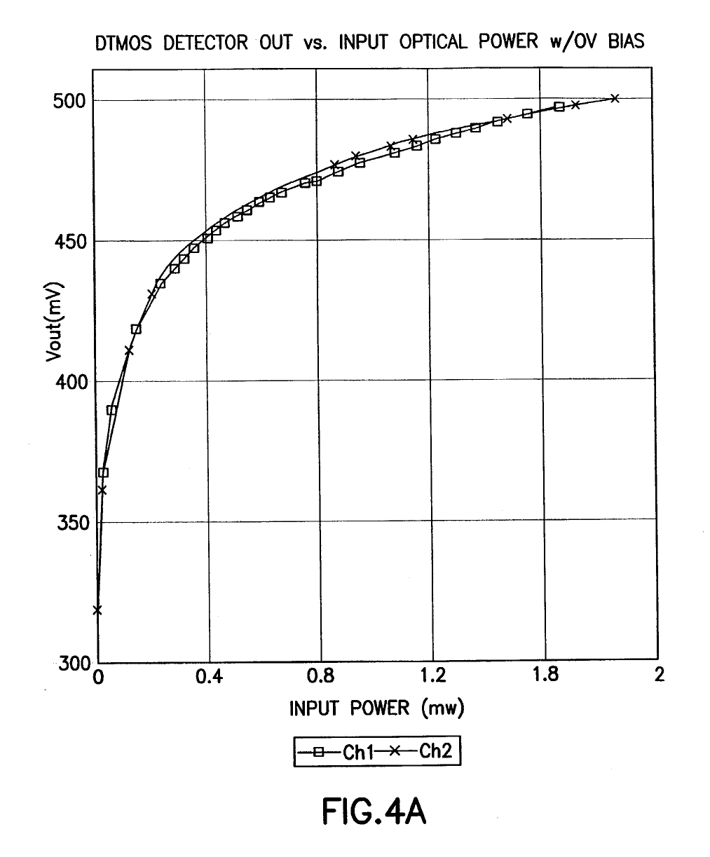

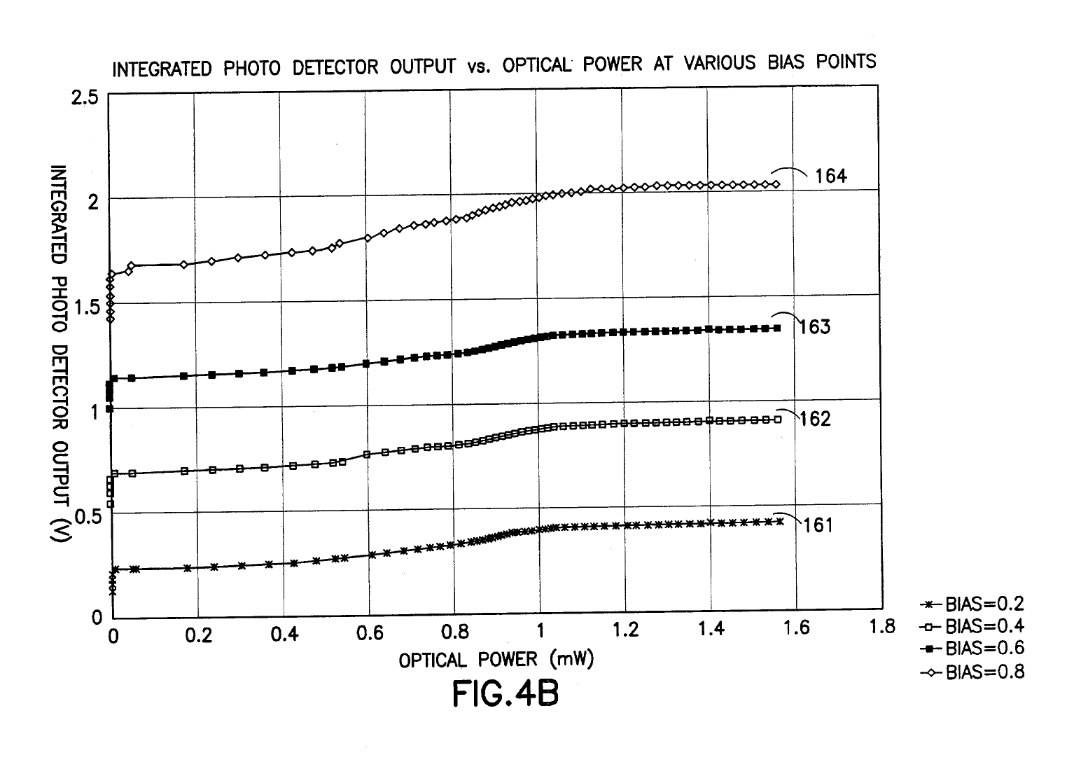

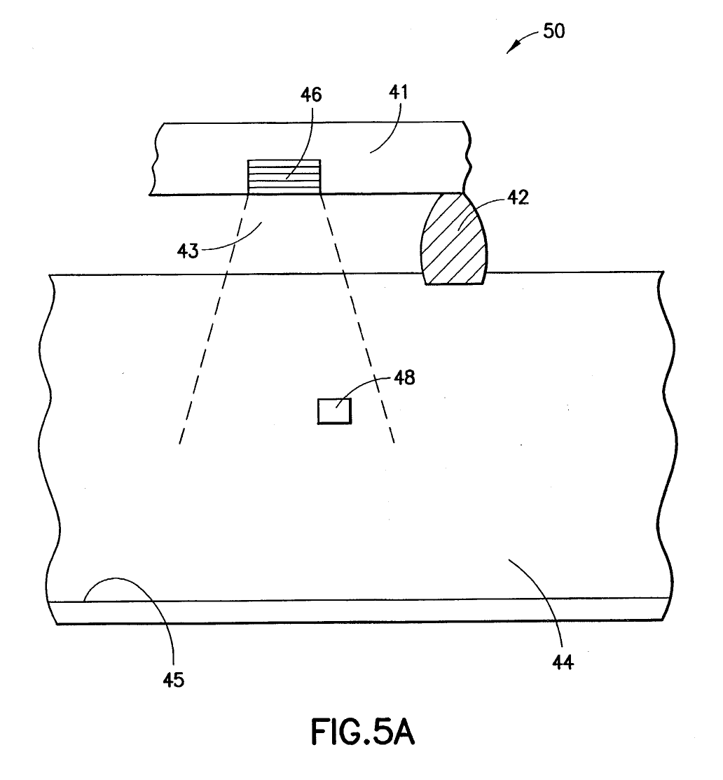

The resopnse of this photodetector was tested. FIG. 4a shows only the output from the DTMOS device with zero volts bias at its source terminal. FIG. 4b shows results in the form of a plot of output voltage vs. input optical power obtained with a photodetector circuit fabricated according to the present invention. Output voltage (V) at the post amplifier is plotted versus input optical power (mW) at several biasing voltages. The detector was biased as follows:

| Example | Bias Voltage (V) |
|---|---|
| 161 | 0.2 |
| 162 | 0.4 |
| 163 | 0.6 |
| 164 | 0.8 |

Alternatively, the source terminal of the DTMOS transistor can be connected to an analogous diode-connected NMOS current source structure as in FIG. 2. The operating point of the DTMOS transistor can be controlled by the bias voltage of a PMOS or NMOS current source.

The photodetector may be positioned with respect to the VCSEL in a variety of ways, which are selected to be suited to the particular application. Transparent substrates offer a great deal of flexibility in configuring the integrated system. The VCSEL is bonded to the transparent substrate by means of an electrically conductive bond, e.g. by the technique of flip chip bonding. The concept of a flip-chip bonded VCSEL laser attached to a silicon-on-insulator transparent substrate which contains active electronics in the silicon layer was described in U.S. patent application Ser. No. 09/658,259, filed Sep. 8, 2000, the disclosure of which is hereby incorporated herein by reference. Three examples of useful configurations are described below, but they are not to be construed as limiting and certainly other configurations employing the general principles of the invention may be envisioned. E.g., the photodetector may monitor the VCSEL output by sampling a small portion of emitted light directly, by virtue of its small size relative to the VCSEL beam. Alternatively, the photodetector may sample light reflected from a surface of the transparent substrate, which may optionally be provided with coatings of reflective material in selected areas. The light may be sampled before or after it passes through the transparent substrate.

The invention may be practiced using silicon on insulator substrates of any type where the substrate transmits most of the light at the wavelength of operation, so that the light that is transmitted through the substrate is usable in the desired application. Silicon-on-glass is an example of a material that can be used (e.g., U.S. Pat. No. 5,395,481, “Method for forming silicon on a glass substrate”). Ultrathin silicon on sapphire technology is very advantageous for the integrated VCSEL/photodetector system. For 850 nm light, less than 1% of the optical power is absorbed in a thin silicon layer of approximately 100 nm thickness. The low loss is a combination of the silicon absorption coefficient at 850 nm and the small area of the DTMOS transistor with respect to the beam size of the VCSEL. This represents an optical power loss of much less than 0.1 dB.

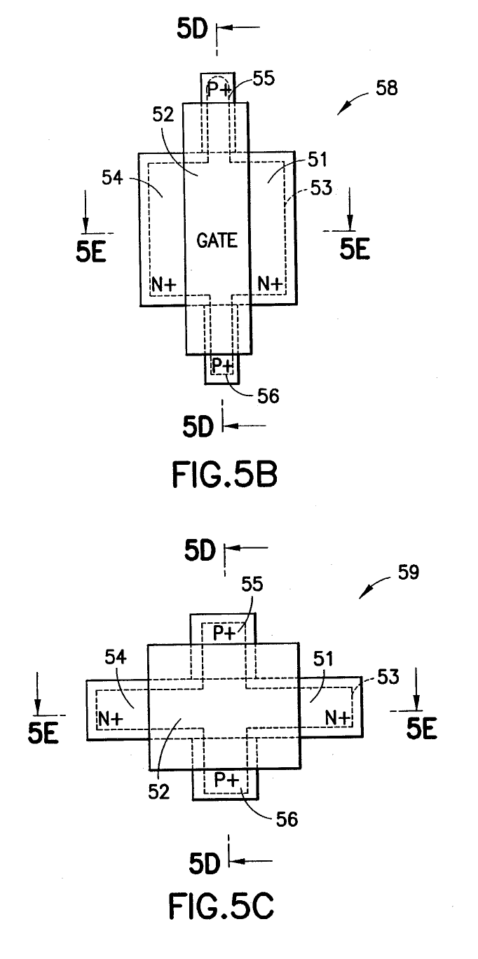

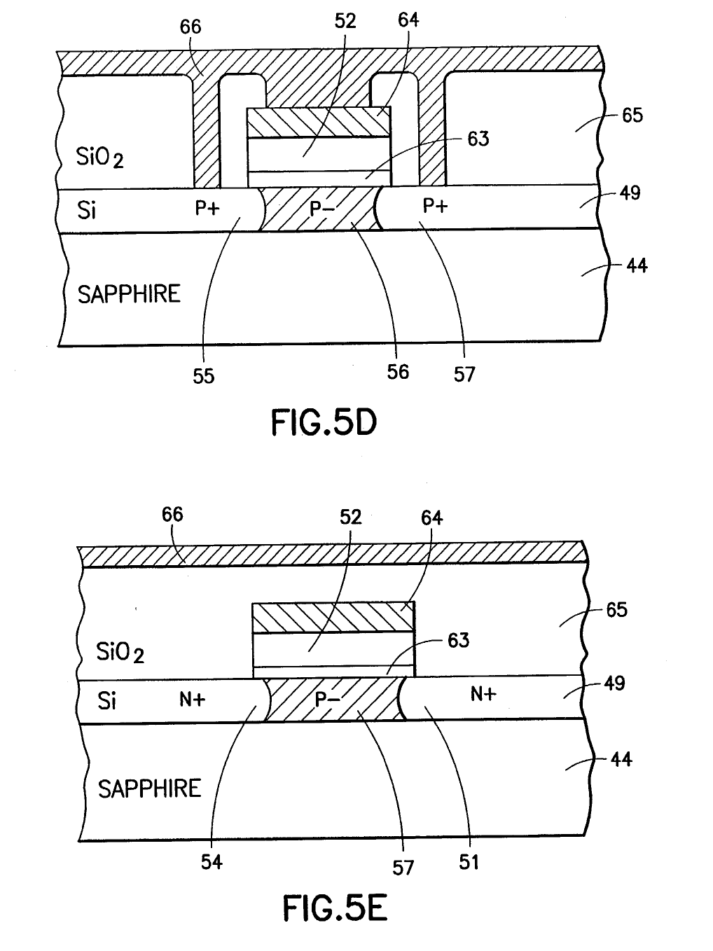

FIG. 5A shows in a highly schematic way integrated VCSEL-photodetector module 50, omitting many aspects such as the flip-chip bond, other circuits, etc., in the interest of illustrating the configuration clearly. Module 50 illustrates one example of a method of positioning of the photodetector with respect to a VCSEL 46 formed in a suitable optoelectronic substrate 41 and flip-chip bonded via electrically conductive bond 42 to sapphire substrate 44. The VCSEL 46 is in electrical communication with a VCSEL driver circuit formed in the thin layer of silicon present in selected areas (not shown) of top surface 45 of transparent substrate 44. The photodetector 48 is positioned in the silicon layer beneath the VCSEL 46 and in the path 43 of light emitted by it. This positioning is made possible by the transparent nature of the sapphire substrate. The light is incident in an approximately vertical direction and a small fraction is absorbed in the body of the detector's DTMOS transistor. This small fraction of light generates a signal that can be used as a feedback control signal for the VCSEL driver circuit For an array of VCSELs, a photodetector may be placed under each VCSEL and the feedback signal can control each VCSEL independently, compensating for VCSEL aging, temperature dependence, and manufacturing tolerances across the array. Because the physical size of the photodetector is small compared to the spot size of the VCSEL, alignment tolerances are very large. This lends the approach well for low cost, high volume manufacturing.

FIGS. 5B and 5C show top view schematics of two layouts of the DTMOS transistor that can be used in this photodetector embodiment. FIG. 5B shows layout 58, in which gate structure 52 may be polysilicon or silicide. Source and drain terminals 51 and 54 and body-gate tie 55 and 56 are in contact with the body or channel region of the transistor, which is not shown in this top view. Dotted line 53 shows the approximate extent of the active area of the transistor. FIG. 5C shows layout 59 which is similar to 58, where the transistors have been fabricated with different aspect ratios.

FIGS. 5D and 5E show cross-sections of the layout 59 shown in FIG. 5C along line A-A′ and B-B′ respectively. The transistor's active region is formed in the epitaxial silicon layer 49 on the sapphire substrate 44. The transistor body 57 is located under the gate polysilicon 52 which is optionally sandwiched with a silicide layer 64. The body is contacted with highly doped silicon of the same polarity as the body (55 and 56). The gate polysilicon is separated from the epitaxial silicon by a dielectric 63. Source 51 and drain 54 terminals are composed of epitaxial silicon doped the opposite polarity from the body. The entire transistor is coated with a dielectric 65 to electrically passivate and physically protect the DTMOS transistor. Metal 66 is used to connect the gate and body terminals together.

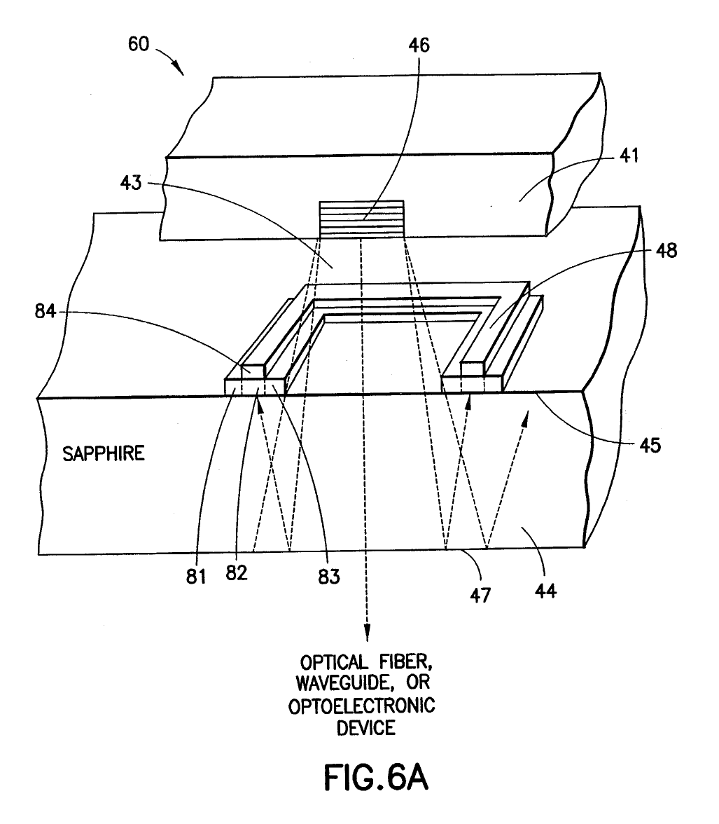

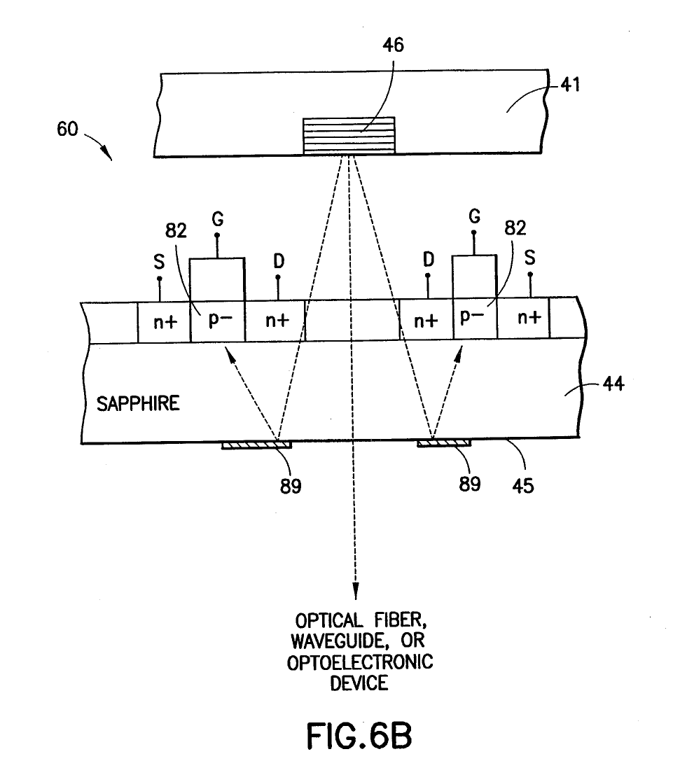

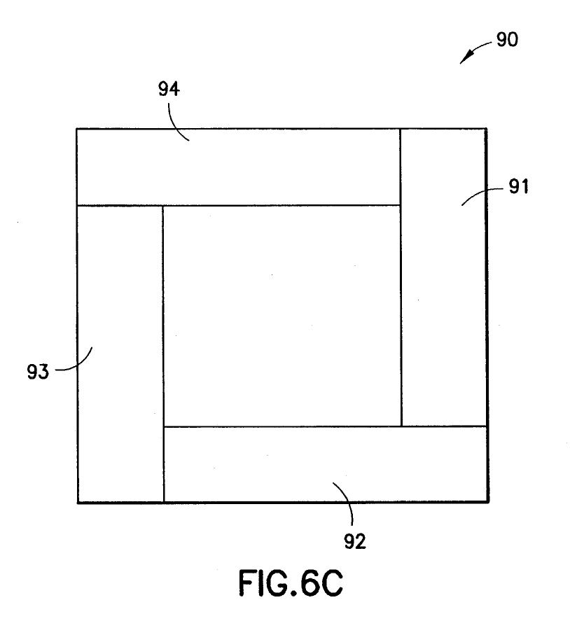

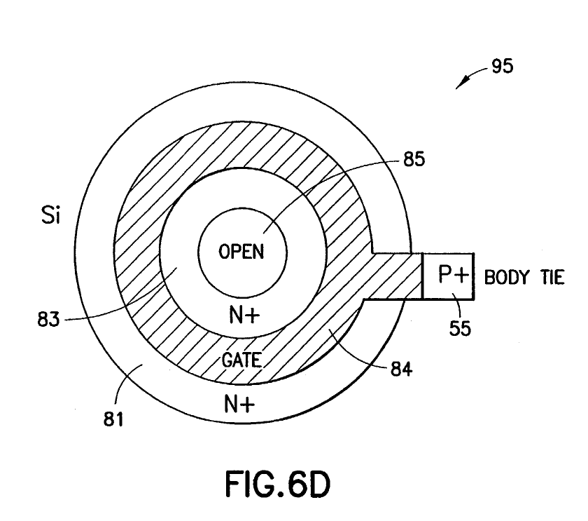

FIG. 6A shows in a highly schematic way a integrated VCSEL-photodetector module 60, omitting many aspects such as the flip-chip bond, other circuits, etc., in the interest of illustrating the configuration clearly. Module 60 illustrates schematically a second example of a method of positioning of the photodetector with respect to a VCSEL 46 in optoelectronic substrate 41, which is flip-chip bonded to the silicon on sapphire substrate 44. The photodetector 48 formed in a silicon layer on top surface 45 of the sapphire substrate 44 is configured to surround the emitted light pathway 43. The DTMOS device is made up of a plurality of DTMOS transistors in parallel electrical connection, i.e. all drains 81 are electrically connected, all sources 83 are electrically connected, etc., so that the plurality of DTMOS transistors behaves electrically as one extended DTMOS device. Light from the VCSEL 46 is reflected from back surface 47 of the sapphire substrate 44 and impinges on the depletion region 82 of the extended DTMOS transistor, beneath gate 84. In this arrangement, gate 84, drains 81, and sources 83 may all be provided with self-aligned silicide (salicide) which will improve performance but is relatively opaque to light. Light path 43 continues through the transparent substrate 44 thereon to make optical connection with an optical waveguide, an optical fiber, an optoelectronic device, etc., as desired in the end-use.

FIG. 6B shows another schematic of the module 60 configuration, showing optional reflective coatings 89 provided to enhance reflection of light into the body regions 82. Coatings 89 may comprise aluminum or any suitable reflective material.

FIG. 6C shows a top view schematic of one example of a DTMOS transistor layout 90 for use in module 60, comprising four DTMOS transistors 91, 92, 93 and 94 which are laid out in a series arrangement to form an annular transistor.

FIG. 6D shows a top view schematic of another example of a DTMOS transistor layout 95 for use in module 60, comprising a circular transistor. The central open area 88 is transparent, allowing an aligned optical fiber to shine down to the wafer back side, from which some light reflects back up to the DTMOS transistor body under the gate 85. The body tie 55 and gate 85 are both contacted together with metal. The source 81 and drain 83 connections are separately contacted with metal.

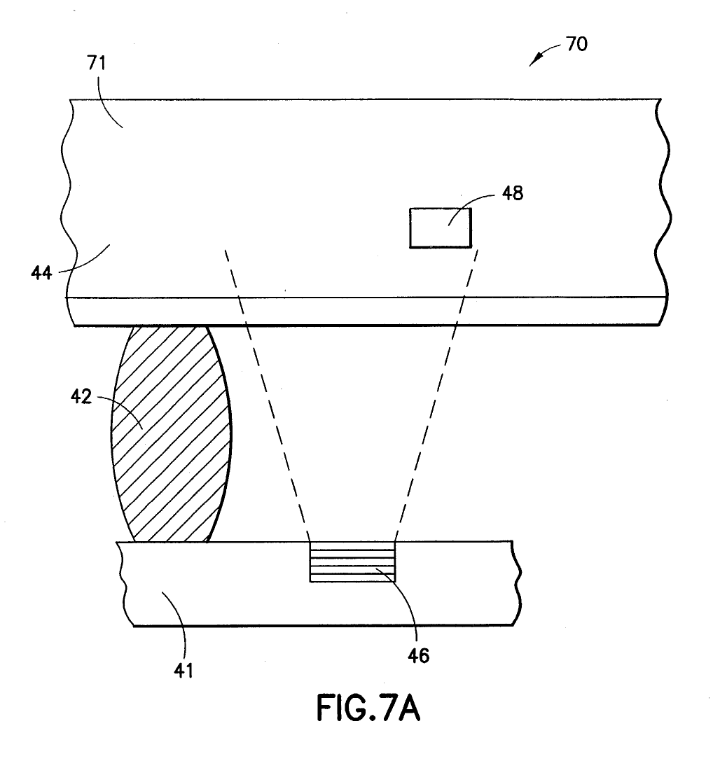

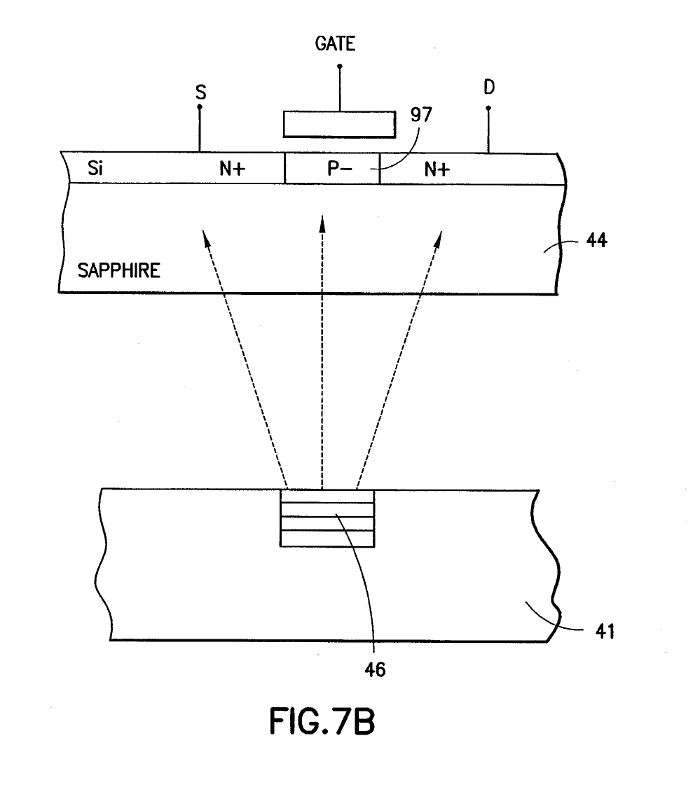

FIG. 7A shows schematically a module 70 which is a third example of a method of positioning of the photodetector with respect to a VCSEL flip chip bonded to a substrate comprising silicon on a transparent insulator. In this instance the illumination from VCSEL 46 is provided directly from the back side of the transparent wafer 44, impinging on the photodetector 48 fabricated on the top side 71 of the substrate. Electrical contact (not shown) between the VCSEL chip 41 and the circuitry on the top side of the transparent substrate can be provided by a through-wafer via, wire bond, or other standard means.

FIG. 7B shows another schematic of module 70, showing the light beam 43 impinging on the body 97 of the DTMOS transistor that is the light sensing element of the photodetector.

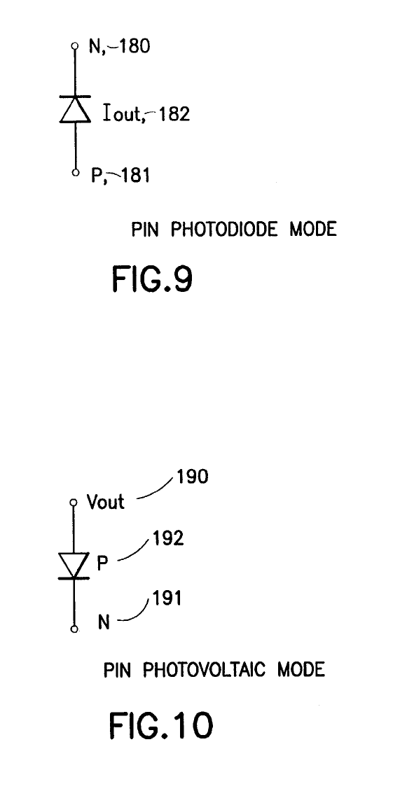

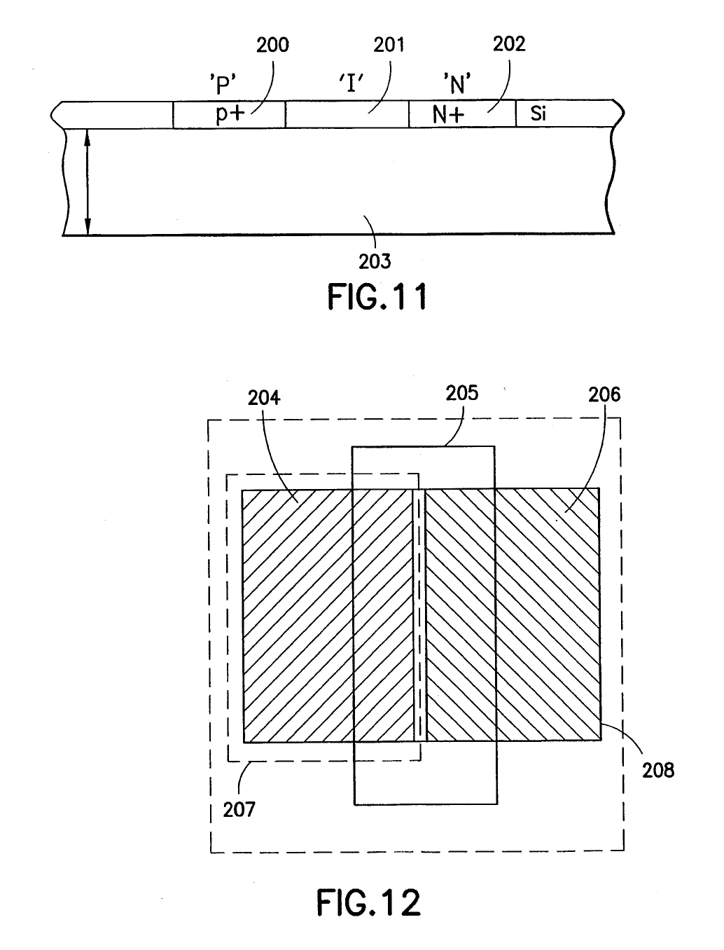

In alternate embodiments, the photodetector may be a “lateral PIN” type photodetector. To form this structure, heavily doped n-type and p-type regions of the thin Si layer in the SOI/SOS process are separated by regions of lightly doped or intrinsic material, as shown in FIG. 11, where 200 is the P side, 201 is intrinsic Si, and 202 is the N side, formed in the Si layer on electrically insulating substrate 203. The resulting PIN diode may be used to detect an optical signal by two general approaches, and variants thereof. In the photodiode approach, shown in FIG. 9, the diode is reverse biased (P-side 181 at lower potential than N-side 180). The current Iₒᵤₜ 182 through the device is proportional to the optical power absorbed by the detector. In the photovoltaic approach as shown in FIG. 10, the diode is open circuited (no terminal current flow through device) and the voltage Vₒᵤₜ 190 that develops across the P-side 192 and N-side 191 is measured. A simple model for the voltage that is measured in this case is Vₒᵤₜ=(kT/q)*ln(1+Iₚ/Iₛ), where k is Boltzman's constant, T is the Kelvin temperature, q is the magnitude of the electron charge, Iₚ is the photocurrent that would be detected in the photodiode mode, and Iₛ is the reverse saturation current of the diode.

FIG. 12 shows the layout layer combination that may be used to create the device in the UTSi process. The width of the central region 201 (intrinsic or low doped p or n) is controlled by the SDBLOCK layer (source/drain block) 205. The SDBLOCK layer 205 is a photoresist layer that blocks the source and drain implants during processing. This dimension may be varied to control the device collection efficiency, speed, and dark current. It is desirable in constructing the actual device layout to avoid the existence of SDBLOCK 205 edges which are not abutted with n-type 202 of p-type 204 LOCOS. The exposed edges are expected to increase Iₛ and potentially noise, and may short-circuit the device depending on the details of how the LOCOS 208 isolation is formed (due to doping along edge of LOCOS that is intended to MOSFETs). Details of implementations which accomplish this are shown below.

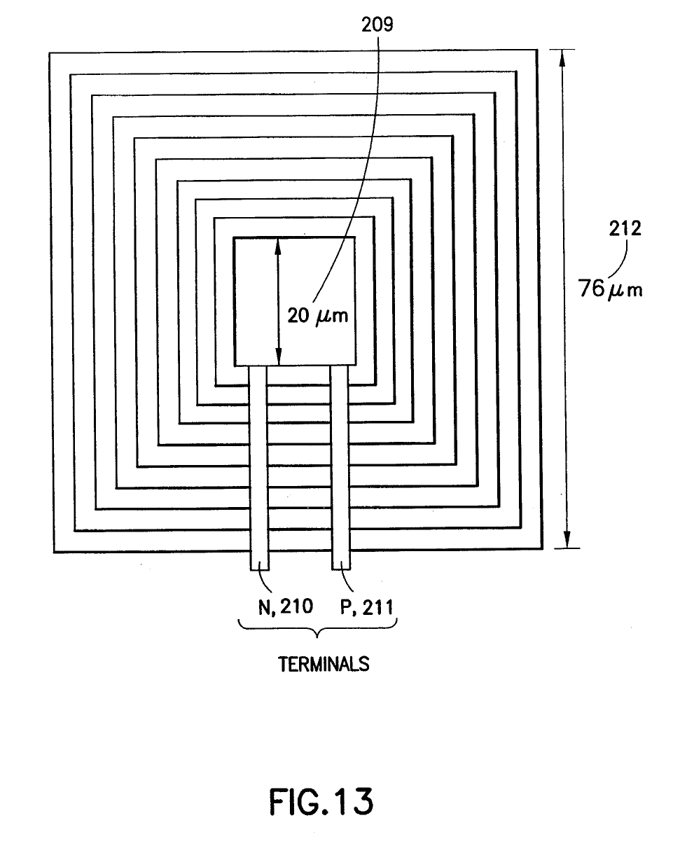

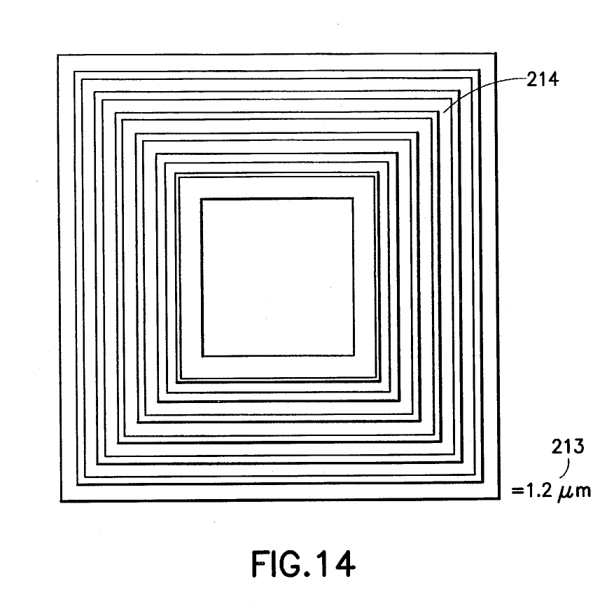

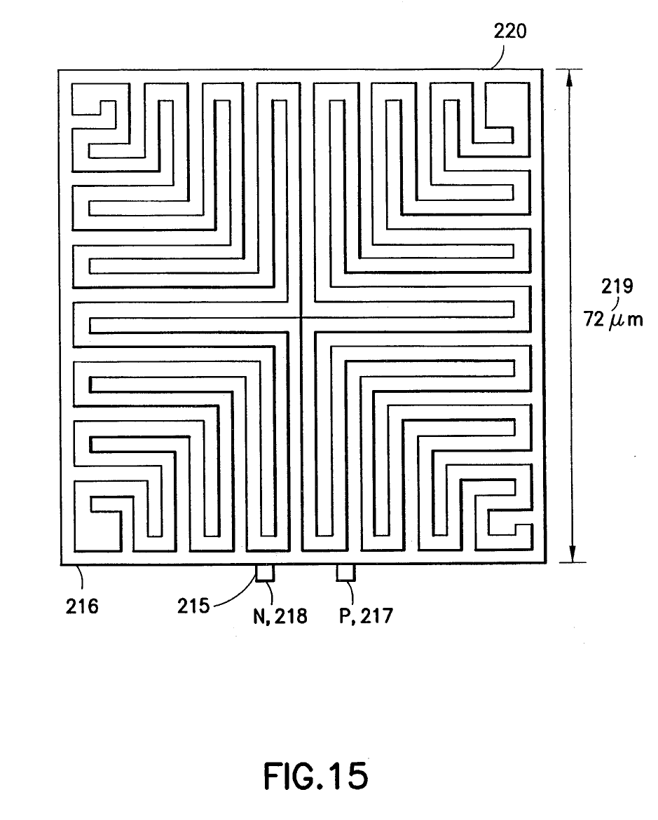

Two general types of layout geometries have been examined. One is the reflection mode device and the other is the transmission mode device. The reflection mode device leaves the direct VCSEL optical path unobstructed to minimize reflection of light into the VCSEL. A layout of one such device is shown in FIG. 13, with only the SDBLOCK 209 layer shown in FIG. 14 for clarity. The detector collects light that is reflected at the back surface of the IC substrate. This device takes an annular geometry and is shown in FIG. 13. This particular device was sized to accompany a particular VCSEL and for use in a particular application. Other sizings will be required for each given circumstance. The device shown has a 20 μm square opening 209 at its center and a 76 μm square outer dimension 212. Other annular geometries (e.g. circular, octagonal, etc. . . . ) are all possible. The 20 μm inner dimension 209 is chosen to guarantee that the 5-10 μm optical beam from the VCSEL will come into contact with the Si making up the detector in spite of +/−5 μm of misalignment. The device consists of concentric rings of P-X-N-X-P-X-N- . . . regions (X representing intrinsic or lightly doped p or n). Note that the closed ring nature of the SDBLOCK regions 214 ensures that there are no exposed edges. The outer dimension of the device is chosen depending on the optical beam profile and on the goals of the device. If the device is to be used in the photo diode mode (measuring photocurrent) then the device area may be maximized, subject to other constraints such as cross talk or area, in order to maximize the photocurrent. If the device is to be used in a photovoltaic mode, them the outer dimension may be optimized to help adjust the Iₚ/Iₛ ratio.

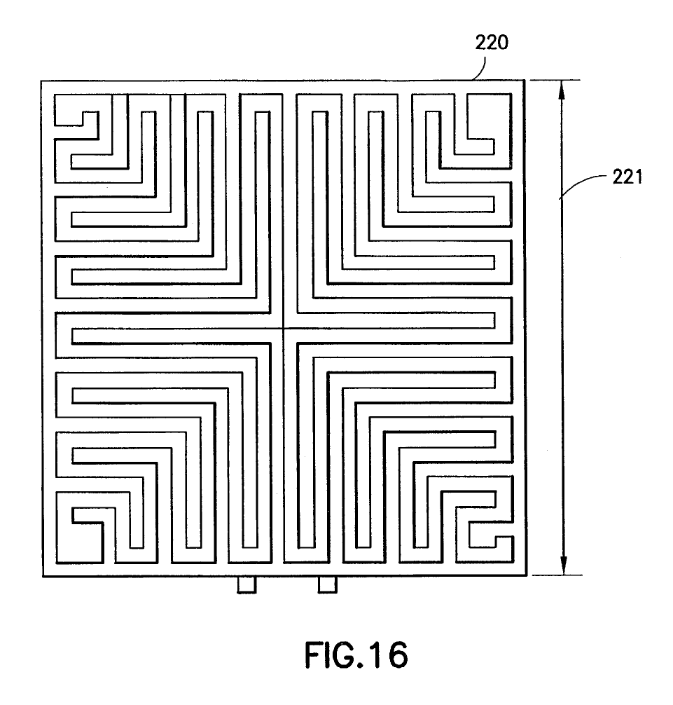

The other geometry examined is the transmission mode device. An example is shown in FIG. 15, with the SDBLOCK layer 220 alone shown in FIG. 16. Here, the active detector area is placed directly in the VCSEL optical path. The detector collects both transmitted light and the reflected signal that was picked up in the reflection mode device. The outer dimension 219 may again be adjusted to control the Iₚ/Iₛ ratio when the devices is used in photovoltaic mode. Also, note that the SBLOCK region 220 takes the form of a closed contour in order to eliminated any exposed edges.

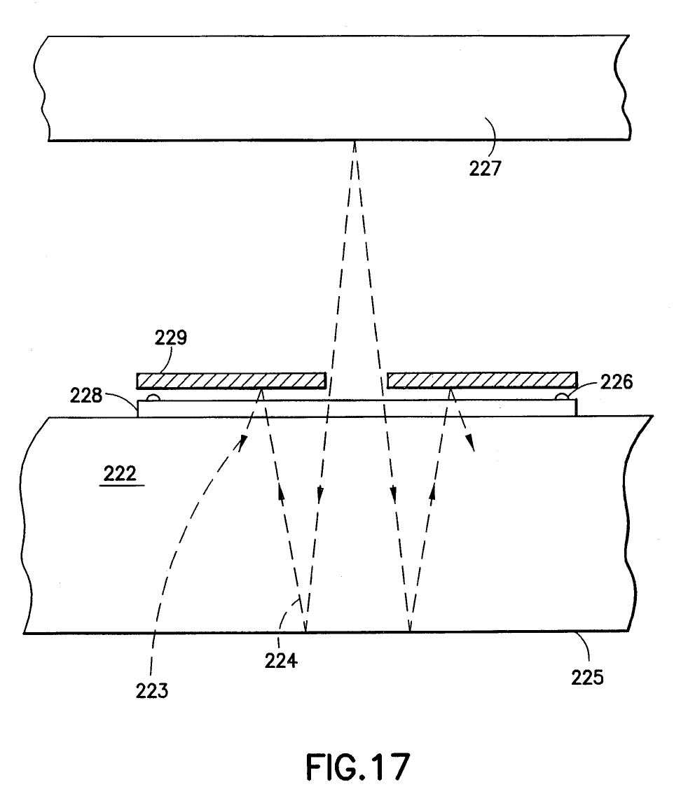

In both types of geometries, a reflective layer 229 may be situated above the device in order to enhance its response. In the examples given above, this was done using Metal-2 layer 229 in the manner shown in FIG. 17.

The invention provides an efficient method for aligning the light source device, e.g., VCSEL, to emit light primarily through the transparent area with some light sampled by the photodetector. The top surface of the sapphire substrate is initially provided with precision alignment features with respect to which all subsequent alignment steps are performed. The electrical features such as circuitry and especially bonding pads are all aligned to the alignment features. Any passive mechanical alignment members, e.g., guide pins, precision guide holes, etc., for aligning the VCSELs to optical receivers, e.g., optical fibers, waveguides, external photodetectors, are formed in or attached to the substrate in precise spatial relationship to the alignment features.

The “alignment features” are physical structures that can be sensed by processing equipment used in subsequent processing steps and may comprise optical or mechanical features. The alignment features may include, for example, electrical traces on the transparent substrate, registration marks on the transparent substrate, mechanical structures such as guide holes formed in the transparent substrate, and the like.

The alignment features are preferably formed by the photolithographic processes that are used to form the electrical circuit devices and connections, and hence they are formed with the extremely high precision characteristic of such processes. Alignment to one set of alignment features on the same side of the substrate minimizes the accumulation of alignment variances and enables good through-substrate optical coupling between a packaged OE device and an external optical receiver or transmitter possessing complementary mechanical alignment members. The location of the bonding pads on the top surface of the sapphire substrate defines the position of the flip-chip bonded VCSEL, which is preferably situated to emit light through a transparent area in the silicon layer and to enable a portion of the emitted light to impinge on the photodetector.

In preferred embodiments, VCSELs are positioned on the silicon on sapphire substrate by the technique of flip-chip bonding. In this technique a chip is flipped over and attached to a substrate or other chip by a solder joint. Hence, two dissimilar chips are brought into intimate electrical and mechanical contact with each other. This technique has been used for combining low temperature infrared (IR) detector arrays with Si readout circuitry. There are commercial machines that can perform this operation with great reliability and repeatability. The VCSEL(s) are provided with and are in electrical contact with regions of conductive material for forming contacts by flip-chip bonding (“bonding pads”), in appropriate sites where electrical connection to the silicon electronic device(s) is intended to be made. Flip-chip solder bump bonding of GaAs-based devices onto silicon integrated circuits is known (e.g., K. W. Goossen et al., IEEE Photonics Technol. Lett., Vol. 5(7), pp. 776-778, 1994). Pu et al. (J. Selected Topics Quantum Electronics, Vol. 5, No. 2, pp. 201-207, 1999) briefly reviewed earlier methods, and developed and compared three new methods for bonding VCSELs to CMOS integrated circuit chips. The methods examined involved coplanar flip-chip bonding using the thermocompression of a gold post into indium-tin solder, top-bottom contact bonding using a solder bond, and top contact bonding wherein the VCSEL is attached to the electronic chip with epoxy. In the practice of the invention, an appropriate bonding technique is selected based on the overall integrated device configuration and properties desired. For example, in one configuration, the metallurgical system comprises Au:Ge at the eutectic ratio (approximately 80:20).

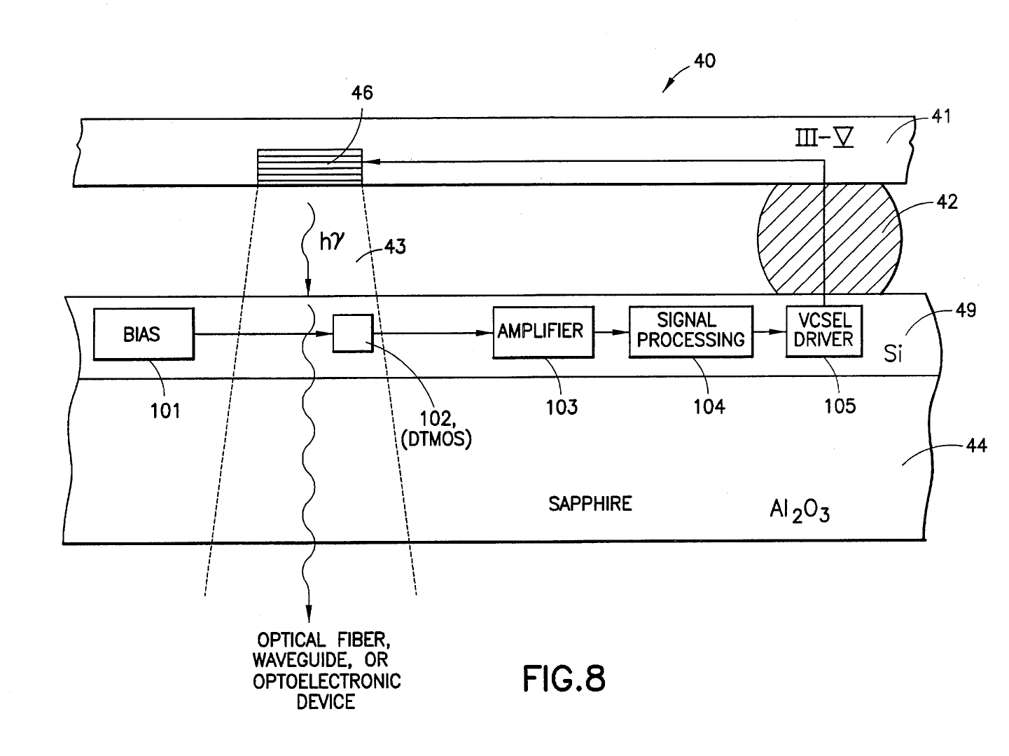

FIG. 8 shows a block diagram illustrating the operation of the integrated VCSEL/photodetector system 40. The relative positioning of the VCSEL and photodetector may be by any arrangement, including but not limited to the configurations shown schematically in FIGS. 5-7. VCSEL 46 is formed in a suitable optoelectronic substrate 41 and emits light in path 43, part of which directly or by reflection impinges on photodetector 102. The photodetector 102 is formed in a thin silicon layer 49 on a transparent substrate 44. The photodetector 102 is biased by biasing circuit 101 and provides an output signal to amplifier 103. Amplifier 103 transmits an amplified signal to signal processing circuit 104, which provides to VCSEL driver circuit 105 a signal which is usable for biasing or in any other suitable way controlling and adjusting the output of the VCSEL driver circuit. The VCSEL driver circuit 105 is in electrical communication with the VCSEL 46 and provides electrical driving input to it.

While the invention has been described herein with reference to various illustrative features, aspects and embodiments, it will be appreciated that the invention is susceptible of variations, modifications and other embodiments, other than those specifically shown and described. The invention is therefore to be broadly interpreted and construed as including all such alternative variations, modifications and other embodiments within its spirit and scope as hereinafter claimed.

1. A light sensing device comprising:
a sapphire substrate including a top surface and a bottom surface;
a silicon layer disposed on the top surface of the sapphire substrate so as to define a transparent portion of the sapphire substrate through which light of a prescribed wavelength may pass; and
a photodetector formed in the silicon layer adjacent the transparent portion of the sapphire substrate.

2. The light sensing device of claim 1 further including:
at least one alignment feature formed on the top surface of the sapphire substrate;
wherein the photodetector is formed in the silicon layer in a prescribed spatial relationship with the at least one alignment feature.

3. The light sensing device of claim 1 further including:
at least one alignment feature formed on the silicon layer disposed on the top surface of the sapphire substrate;
wherein the photodetector is formed in the silicon layer in a prescribed spatial relationship with the at least one alignment feature.

4. The light sensing device of claim 1 further including:
a metal layer disposed on the top surface of the sapphire substrate;
at least one alignment feature formed in the metal layer disposed on the top surface of the sapphire substrate;
wherein the photodetector is formed in the silicon layer in a prescribed spatial relationship with the at least one alignment feature.

5. The light sensing device of claim 1 further including:
at least one bonding pad disposed on the top surface of the sapphire substrate;
wherein the photodetector is formed in the silicon layer in a prescribed spatial relationship with the at least one bonding pad.

6. The sensing device of claim 5 wherein the at least one bonding pad includes at least one light source bonding pad.

7. The light sensing device of claim 1 further including:
at least one alignment feature formed on the silicon layer disposed on the top surface of the sapphire substrate;
a metal layer disposed on the top surface of the sapphire substrate; and
at least one alignment feature formed in the metal layer disposed on the top surface of the sapphire substrate;
wherein the photodetector is formed in the silicon layer in a prescribed spatial relationship with the at least one alignment feature formed in the silicon layer; and
wherein the photodetector is formed in the silicon layer in a prescribed spatial relationship with the at least one alignment feature formed in the metal layer.

8. The light sensing device of claim 1 wherein,
the transparent portion serves as an alignment feature; and
the photodetector is formed in the silicon layer in a prescribed spatial relationship with the transparent portion.

9. The light sensing device of claim 1 wherein a silicon dioxide layer overlays the transparent portion of the sapphire substrate.

10. The light sensing device of claim 1 wherein the prescribed wavelength includes a wavelength of about 850 nanometers.

11. The light sensing device of claim 1,
wherein the photodetector includes a dynamic threshold metal oxide semiconductor (DTMOS) transistor.

12. The light sensing device of claim 1,
wherein the photodetector includes multiple dynamic threshold metal oxide semiconductor (DTMOS) transistors.

13. The light sensing device of claim 1,
wherein the photodetector includes a PiN diode.

14. The light sensing device of claim 1,
wherein the photodetector includes a lateral PiN diode.

15. The light sensing device of claim 1,
wherein the photodetector includes multiple PiN diodes.

16. The light sensing device of claim 1,
wherein the photodetector substantially surrounds the clear portion of the sapphire substrate.

17. The light sensor of claim 1 wherein:
the photodetector includes multiple dynamic threshold metal oxide semiconductor (DTMOS) transistors; and
the multiple DTMOS transistors are formed in the silicon layer so as to substantially surround the clear portion of the sapphire substrate.

18. The light sensor of claim 1 wherein:
the photodetector includes multiple PiN diodes; and
the multiple PiN diodes are formed in the silicon layer so as to substantially surround the clear portion of the sapphire substrate.

19. A method of determining intensity of light emitted from a light source comprising:
emitting light from the light source onto the transparent portion of the sapphire substrate of the device of claim 1; and
detecting an intensity level of the emitted light that is reflected onto the photodetector from the bottom surface of the sapphire substrate.

20. A light sensing device comprising:
a sapphire substrate including a top surface and a bottom surface;
a silicon layer disposed on the top surface of the sapphire substrate so as to define multiple respective transparent portions of the sapphire substrate through which light of a prescribed wavelength may pass; and
multiple respective photodetectors formed in the silicon layer adjacent different respective transparent portions of the sapphire substrate.

21. The light sensing device of claim 20 further including:
at least one alignment feature formed on the top surface of the sapphire substrate; and
wherein the multiple respective photodetectors are formed in the silicon layer in prescribed spatial relationships with the at least one alignment feature.

22. The light sensing device of claim 20 further including:
at least one alignment feature formed on the silicon layer disposed on the top surface of the sapphire substrate;
wherein the multiple photodetectors are formed in the silicon layer in prescribed spatial relationships with the at least one alignment feature.

23. The light sensing device of claim 20 further including:
a metal layer disposed on the top surface of the sapphire substrate;
at least one alignment feature formed in the metal layer disposed on the top surface of the sapphire substrate;
wherein the multiple photodetectors are formed in the silicon layer in prescribed spatial relationships with the at least one alignment feature.

24. The light sensing device of claim 20 further including:
at least one bonding pad disposed on the top surface of the sapphire substrate;
wherein the multiple photodetectors are formed in the silicon layer in prescribed spatial relationships with the at least one bonding pad.

25. The sensing device of claim 20 wherein the at least one bonding pad includes at least one light source bonding pad.

26. The light sensing device of claim 20 further including:
at least one alignment feature formed on the silicon layer disposed on the top surface of the sapphire substrate;
a metal layer disposed on the top surface of the sapphire substrate; and
at least one alignment feature formed in the metal layer disposed on the top surface of the sapphire substrate;
wherein the multiple photodetectors are formed in the silicon layer in prescribed spatial relationships with the at least one alignment feature formed in the silicon layer; and
wherein the multiple photodetectors are formed in the silicon layer in prescribed spatial relationships with the at least one alignment feature formed in the metal layer.

27. The light sensing device of claim 20 wherein,
the transparent portion serves as an alignment feature; and
the multiple photodetectors are formed in the silicon layer in prescribed spatial relationships with the transparent portion.

28. The light sensing device of claim 20 wherein a silicon dioxide layer overlays the clear portion of the sapphire substrate.

29. The light sensing device of claim 20 wherein the prescribed wavelength includes a wavelength of about 850 nanometers.

30. The light sensing device of claim 20,
wherein the multiple respective photodetectors include multiple respective dynamic threshold metal oxide semiconductor (DTMOS) transistors.

31. The light sensing device of claim 20,
wherein the multiple respective photodetectors include multiple respective PiN diodes.

32. The light sensing device of claim 20,
wherein the multiple respective photodetectors include multiple respective lateral PiN diodes.

33. The light sensing device of claim 20,
wherein the multiple respective photodetectors are formed in the silicon layer so as to substantially surround respective clear portions of the sapphire substrate.

34. The light sensor of claim 20 wherein:
the multiple respective photodetectors include multiple respective dynamic threshold metal oxide semiconductor (DTMOS) transistors; and
the multiple respective DTMOS transistors are formed in the silicon layer so as to substantially surround respective clear portions of the sapphire substrate.

35. The light sensor of claim 20 wherein:
the multiple respective photodetectors include multiple PiN diodes; and
the multiple respective PiN diodes are formed in the silicon layer so as to substantially surround respective clear portions of the sapphire substrate.

36. The light sensor of claim 20 wherein at least one photodetector is formed in the silicon layer adjacent to each transparent portion.

37. The light sensor of claim 20 wherein respective photodetectors are formed in the silicon layer adjacent to selected transparent portions.

38. A method of determining light intensity of light emitted from each of multiple respective light sources comprising:
emitting respective light from each light source onto a different respective transparent portion of the sapphire substrate of the device of claim 20; and
detecting respective light intensity levels of respective emitted light that is reflected onto respective photodetectors from a bottom surface of the sapphire.

39. An optical device comprising:
a sapphire substrate including a top surface and a bottom surface;
a silicon layer disposed on the top surface of the sapphire substrate so as to define a transparent portion of the sapphire substrate through which light of a prescribed wavelength may pass;
a photodetector formed in the silicon layer adjacent the transparent portion of the sapphire substrate;
a light source disposed to emit light onto the transparent portion of the sapphire substrate adjacent to the photodetector; and
a light source control circuit electrically coupled to an output of the photodetector and to a control input of the light source.

40. The optical device of claim 39 wherein,
the light source includes a vertical cavity surface-emitting laser (VCSEL); and
the light source control circuit includes a VCSEL driver circuit.

41. The optical device of claim 39 further including:
at least one alignment feature formed on the top surface of the sapphire substrate;
wherein the photodetector is formed in the silicon layer in a prescribed spatial relationship with the at least one alignment feature; and
wherein the light source is disposed in a prescribed spatial relationship with the at least one alignment feature.

42. The light sensing device of claim 39 further including:
at least one alignment feature formed on the silicon layer disposed on the top surface of the sapphire substrate;
wherein the photodetector is formed in the silicon layer in a prescribed spatial relationship with the at least one alignment feature; and
wherein the light source is disposed in a prescribed spatial relationship with the at least one alignment feature.

43. The light sensing device of claim 39 further including:
a metal layer disposed on the top surface of the sapphire substrate;
at least one alignment feature formed in the metal layer disposed on the top surface of the sapphire substrate;
wherein the photodetector is formed in the silicon layer in a prescribed spatial relationship with the at least one alignment feature; and
wherein the light source is disposed in a prescribed spatial relationship with the at least one alignment feature.

44. The light sensing device of claim 39 further including:
at least one bonding pad disposed on the top surface of the sapphire substrate;
wherein the photodetector is formed in the silicon layer in a prescribed spatial relationship with the at least one bonding pad; and
wherein the light source is disposed in a prescribed spatial relationship with the at least one bonding pad.

45. The sensing device of claim 39 wherein the at least one bonding pad includes at least one light source bonding pad.

46. The light sensing device of claim 39 further including:
at least one alignment feature formed on the silicon layer disposed on the top surface of the sapphire substrate;
a metal layer disposed on the top surface of the sapphire substrate; and
at least one alignment feature formed in the metal layer disposed on the top surface of the sapphire substrate;
wherein the photodetector is formed in the silicon layer in a prescribed spatial relationship with the at least one alignment feature formed in the silicon layer;
wherein the photodetector is formed in the silicon layer in a prescribed spatial relationship with the at least one alignment feature formed in the metal layer;
wherein the light source is disposed in a prescribed spatial relationship with the at least one alignment feature formed in the silicon layer; and
wherein the light source is disposed in a prescribed spatial relationship with the at least one alignment feature formed in the metal layer.

47. The light sensing device of claim 39,
wherein at least one transparent portion serves as an alignment feature;
wherein the photodetector is formed in the silicon layer in a prescribed spatial relationship with the at least one transparent portion; and
wherein the light source is disposed in a prescribed spatial relationship with the at least one transparent portion.

48. The optical device of claim 39,
wherein the sapphire substrate and the light source are disposed relative to one another such that a top surface of the sapphire substrate with the silicon layer formed thereon faces toward the light source; and
wherein the photodetector and the light source are disposed relative to one another such that a sufficient amount of light emitted by the light source into the transparent portion reflects onto the photodetector, from the bottom surface of the sapphire substrate, to cause the photodetector to produce an output signal indicative of emitted light power level.

49. The optical device of claim 39 further including:
at least one alignment feature formed on the top surface of the sapphire substrate;
wherein the photodetector is formed in the silicon layer in a prescribed spatial relationship with the at least one alignment feature; and
wherein the light source is disposed in a prescribed spatial relationship with the at least one alignment feature;
wherein the sapphire substrate and the light source are disposed relative to one another such that a top surface of the sapphire substrate with the silicon layer formed thereon faces toward the light source; and
wherein the photodetector and the light source are aligned with respect to the at least one alignment feature such that a sufficient amount of light emitted by the light source into the transparent portion reflects onto the photodetector, from a bottom surface of the sapphire substrate, to cause the photodetector to produce an output signal indicative of emitted light power level.

50. The optical device of claim 39,
wherein the sapphire substrate and the light source are disposed relative to one another such that a top surface of the sapphire substrate with the silicon layer formed thereon faces toward the light source; and
wherein the photodetector and the light source are aligned with one another such that approximately 1-10% of light emitted by the light source into the clear portion reflects onto the photodetector from a bottom surface of the sapphire substrate.

51. The optical device of claim 39 wherein the light source control circuit includes a vertical cavity surface-emitting laser (VCSEL) driver is formed in the silicon layer on the sapphire substrate.

52. The optical device of claim 39 wherein,
the sapphire substrate and light source are disposed relative to one another such that a bottom surface of the sapphire substrate faces toward the light source which emits light through such bottom surface and through a body of the sapphire substrate and through the transparent portion of the sapphire substrate adjacent to the photodetector and onto the photodetector.

53. The optical device of claim 39 further including:
signal processing circuitry coupled to process an output provided by the photodetector.

54. The optical device of claim 39 further including:
signal processing circuitry formed in the silicon layer on the sapphire substrate and coupled to process an output provided by the photodetector.

55. An optical device comprising:
a sapphire substrate including a top surface and a bottom surface;
a silicon layer disposed on the top surface of the sapphire substrate so as to define multiple respective transparent portions of the sapphire substrate through which light of a prescribed wavelength may pass;
multiple respective photodetectors formed in the silicon layer adjacent the transparent portions of the sapphire substrate;
multiple respective light sources disposed to emit light into respective transparent portions of the sapphire substrate adjacent respective photodetectors; and
at least one respective light source control circuit electrically coupled to a respective output of at least one respective photodetector and to at least one respective control input of a respective light source.

56. The optical device of claim 55 further including:
at least one alignment feature formed on the top surface of the sapphire substrate; and
wherein the multiple respective photodetectors are formed in the silicon layer in prescribed spatial relationships with the at least one alignment feature.

57. The light sensing device of claim 55 further including:
at least one alignment feature formed on the silicon layer disposed on the top surface of the sapphire substrate;
wherein the multiple photodetectors are formed in the silicon layer in prescribed spatial relationships with the at least one alignment feature.

58. The light sensing device of claim 55 further including:
a metal layer disposed on the top surface of the sapphire substrate;
at least one alignment feature formed in the metal layer disposed on the top surface of the sapphire substrate;
wherein the multiple photodetectors are formed in the silicon layer in prescribed spatial relationships with the at least one alignment feature.

59. The light sensing device of claim 55 further including:
at least one bonding pad disposed on the top surface of the sapphire substrate;
wherein the multiple photodetectors are formed in the silicon layer in prescribed spatial relationships with the at least one bonding pad.

60. The sensing device of claim 55 wherein the at least one bonding pad includes at least one light source bonding pad.

61. The light sensing device of claim 55 further including:
at least one alignment feature formed on the silicon layer disposed on the top surface of the sapphire substrate;
a metal layer disposed on the top surface of the sapphire substrate; and
at least one alignment feature formed in the metal layer disposed on the top surface of the sapphire substrate;
wherein the multiple photodetectors are formed in the silicon layer in prescribed spatial relationships with the at least one alignment feature formed in the silicon layer; and
wherein the multiple photodetectors are formed in the silicon layer in prescribed spatial relationships with the at least one alignment feature formed in the metal layer.

62. The light sensing device of claim 55 wherein,
the transparent portion serves as an alignment feature; and
the multiple photodetectors are formed in the silicon layer in prescribed spatial relationships with the transparent portion.

63. The light sensing device of claim 55 wherein a silicon dioxide layer overlays the clear portion of the sapphire substrate.

64. The light sensing device of claim 55 wherein the prescribed wavelength includes a wavelength of about 850 nanometers.

65. The optical device of claim 55 wherein,
respective light sources include a vertical cavity surface-emitting lasers (VCSELs); and
the at least one light source control circuit includes a respective VCSEL driver circuit.

66. The optical device of claim 55,
wherein the sapphire substrate and the respective light sources are disposed relative to one another such that a top surface of the sapphire substrate with the silicon layer formed thereon faces toward the respective light sources; and
wherein respective photodetectors and respective light sources are disposed relative to one another such that a sufficient amount of respective light emitted by respective light sources into respective clear portions reflects onto respective photodetectors, from a bottom surface of the sapphire substrate, to cause the respective photodetectors to produce respective output signals indicative of respective emitted light power levels.

67. The optical device of claim 55 further including:
at least one alignment feature formed on a top surface of the sapphire substrate;
wherein respective photodetectors are formed in the silicon layer in a prescribed spatial relationship with the at least one alignment feature; and
wherein respective light sources are disposed in prescribed spatial relationships with the at least one alignment feature;
wherein the sapphire substrate and the respective light sources are disposed relative to one another such that a top surface of the sapphire substrate with the silicon layer formed thereon faces toward the respective light sources; and
wherein respective photodetectors and respective light sources are aligned with respect to the at least one alignment feature such that a sufficient amount of respective light emitted by respective light sources into respective clear portions reflects onto respective photodetectors, from the bottom surface of the sapphire, to cause respective photodetectors to produce respective output signals indicative of respective emitted light power levels.

68. The optical device of claim 55,
wherein the sapphire substrate and the light source are disposed relative to one another such that a top surface of the sapphire substrate with the silicon layer formed thereon faces toward the light source; and
wherein respective photodetectors and respective light sources are aligned with one another such that approximately 1-10% of respective light emitted by respective light sources into respective clear portions reflects onto respective photodetectors from a bottom surface of the sapphire substrate.

69. The optical device of claim 55 wherein,
the sapphire substrate and respective light sources are disposed relative to one another such that a bottom surface of the sapphire substrate faces toward the respective light source which emits light through such bottom surface and through a body of the sapphire substrate and through respective transparent portions of the sapphire substrate adjacent to respective photodetectors and onto respective photodetectors.

70. The optical device of claim 55 further including:
signal processing circuitry coupled to process respective outputs provided by respective photodetectors.

71. The optical device of claim 55 further including:
signal processing circuitry formed in the silicon layer on the sapphire substrate and coupled to process respective outputs provided by respective photodetectors.

72. The light sensor of claim 55 wherein at least one photodetector is formed in the silicon layer adjacent to each transparent portion.

73. The light sensor of claim 55 wherein respective photodetectors are formed in the silicon layer adjacent to selected transparent portions.

74. The light sensor of claim 55 wherein,
respective photodectors are formed in the silicon layer adjacent to selected transparent portions; and
at least one of the multiple photodetectors provides an output signal that controls more than one light source.

75. A photodetector comprising:
a sapphire substrate with a layer of silicon disposed thereon;
a first NMOS transistor formed in the silicon layer and including first and second source/drain (S/D) terminals a gate and a transistor body region and in which the first source drain terminal is electrically coupled to a supply voltage and in which the gate is electrically connected to the body region;
an amplifier circuit formed in the silicon layer and electrically coupled between the supply voltage and the effective ground and including a second NMOS transistor with a gate electrically connected to the gate of the first NMOS transistor and including an output terminal that provides an output voltage that represents an amplified version of the second NMOS transistor gate voltage; and
a bias terminal electrically connnected to the second S/D terminal of the first NMOS transistor.

76. A method of operating the photodetector of claim 75 comprising:
illuminating the photodetector with a light source;
providing a bias voltage to the bias terminal so as to set an operating point of the second NMOS transistor such that a small change in light intensity illuminating the first NMOS transistor causes a large change in output voltage of the amplifier circuit.
